(19) United States
(12) Patent Application Publication
(10) Pub. No.: US 2026/0099646 A1
(43) Pub. Date: Apr. 9, 2026

(54) TECHNIQUES FOR MODELING ENVIRONMENTS USING LOCAL AND GLOBAL MODELS

(71) Applicant: PolArctic LLC, Stafford, VA (US)

(72) Inventors: Leslie Ann CANAVERA, Stafford, VA (US); Lauren Brooke DECKER, Las Vegas, NV (US); Christopher Rex CURRY, Fredericksburg, VA (US)

(21) Appl. No.: 18/907,718

(22) Filed: Oct. 7, 2024

(51) Int. Cl. G06F 30/27

(52) U.S. Cl. CPC G06F 30/27; G06N 5/043

(57) ABSTRACT

A method of modeling one or more agents within an environment may comprise: determining, by a local continuous model, one or more local continuous aspects of a local area proximate to the one or more agents; determining, by a local discrete model, one or more local discrete aspects of a local area proximate to the one or more agents; determining, by a global continuous model, one or more global continuous aspects of the environment; and providing a third data packet a modeling system comprising one or more agent models, each of the one or more agent models associated with a respective agent of the one or more agents; and using the third data packet, determining, via the one or more agent models, one or more behaviors of the one or more agents.

### GOVERNMENT LICENSE RIGHTS

This invention was made with government support under a Small Business Innovation Research Grant awarded by the National Science Foundation. The government has certain rights in the invention.

### TECHNICAL FIELD

Various aspects of this disclosure relate generally to techniques for modeling environments, and, more particularly, agent orchestration systems and methods for modeling environments using local and global models.

### BACKGROUND

Some modeling systems exist for modeling actors within environments. But these models are generally limited to modeling a particular group of entities (e.g., one species) alone and fail to consider relevant external forces, which may render the modeling systems far less accurate. Therefore, a need exists for systems for modeling environments that account for relevant factors.

The background description provided herein is for the purpose of generally presenting the context of the disclosure. Unless otherwise indicated herein, the materials described in this section are not prior art to the claims in this application and are not admitted to be prior art, or suggestions of the prior art, by inclusion in this section.

### SUMMARY OF THE DISCLOSURE

Certain aspects of the disclosure relate to methods and systems for modeling environments such as ecosystems. A method of modeling one or more agents within an environment may comprise: determining, by a local continuous model, one or more local continuous aspects of a local area proximate to the one or more agents; constructing, by the local continuous model, a first data packet comprising first data reflecting the one or more local continuous aspects; providing the first data packet to a local discrete model; determining, by the local discrete model, one or more local discrete aspects of a local area proximate to the one or more agents; constructing, by the local discrete model, a second data packet comprising the first data and second data reflecting the one or more local discrete aspects; providing the second data packet to a global continuous model; determining, by the global continuous model, one or more global continuous aspects of the environment; constructing, by the global continuous model, a third data packet including the first data, the second data, and third data reflecting the one or more global continuous aspects; providing the third data packet a modeling system comprising one or more agent models, each of the one or more agent models associated with a respective agent of the one or more agents; and using the third data packet, determining, via the one or more agent models, one or more behaviors of the one or more agents.

Any of the aspects disclosed herein may have any of the following features. The first data includes callback indicators to the local continuous model. The second data includes callback indicators to the local discrete model. Using the third data packet includes making callbacks to the local continuous model and the local discrete model based on the callback indicators. In aspects, the one or more local continuous aspects are one or more first local continuous aspects determined at a first time, and the method further comprises providing the one or more behaviors of the one or more agents to the local continuous model and determining, by the local continuous model, one or more second local continuous aspects of the local area proximate to the one or more agents at a second time. The one or more agents include agents of a first class and agents of a second class, and wherein the one or more agent models include a first machine learning model trained to model the first class and a second machine learning model trained to model the second class. The one or more agent models include a plurality of instantiations of the first machine learning model, each instantiation of the first machine learning model configured to model an agent of the first class, and a plurality of instantiations of the second machine learning model, each instantiation of the second machine learning model configured to model an agent of the second class. The one or more agent models includes a plurality of instantiations of the one or more agent models, and wherein at least some of the plurality of instantiations of the one or more agent models have different parameters or weights from one another. The method may further include receiving, from an optimization or control module, a set of counterfactual parameters that indicate a change to one or more conditions of the environment; and providing the set of counterfactual parameters to the one or more agent models. In aspects, the global continuous model is an energy-based model. In aspects, the environment is an ocean, and wherein the one or more agents include a ship or an animal.

A system for modeling one or more agents within an environment may comprise: at least one data storage device storing instructions for modeling one or more agents within an environment; and at least one processor configured to execute the instructions to perform operations comprising: determining, by a local continuous model, one or more local continuous aspects of a local area proximate to the one or more agents; constructing, by the local continuous model, a first data packet comprising first data reflecting the one or more local continuous aspects; providing the first data packet to a local discrete model; determining, by the local discrete model, one or more local discrete aspects of a local area proximate to the one or more agents; constructing, by the local discrete model, a second data packet comprising the first data and second data reflecting the one or more local discrete aspects; providing the second data packet to a global continuous model; determining, by the global continuous model, one or more global continuous aspects of the environment; constructing, by the global continuous model, a third data packet including the first data, the second data, and third data reflecting the one or more global continuous aspects; providing the third data packet a modeling system comprising one or more agent models, each of the one or more agent models associated with a respective agent of the one or more agents; and using the third data packet, determining, via the one or more agent models, one or more behaviors of the one or more agents.

A non-transitory computer-readable medium may store instructions that, when executed by one or more processors, cause the one or more processors to perform a method for modeling one or more agents within an environment, the method comprising: determining, by a local continuous model, one or more local continuous aspects of a local area proximate to the one or more agents; constructing, by the local continuous model, a first data packet comprising first data reflecting the one or more local continuous aspects; providing the first data packet to a local discrete model; determining, by the local discrete model, one or more local discrete aspects of a local area proximate to the one or more agents; constructing, by the local discrete model, a second data packet comprising the first data and second data reflecting the one or more local discrete aspects; providing the second data packet to a global continuous model; determining, by the global continuous model, one or more global continuous aspects of the environment; constructing, by the global continuous model, a third data packet including the first data, the second data, and third data reflecting the one or more global continuous aspects; providing the third data packet a modeling system comprising one or more agent models, each of the one or more agent models associated with a respective agent of the one or more agents; and using the third data packet, determining, via the one or more agent models, one or more behaviors of the one or more agents.

It is to be understood that both the foregoing general description and the following detailed description are exemplary and explanatory only and are not restrictive of the disclosed embodiments, as claimed.

### BRIEF DESCRIPTION OF THE DRAWINGS

The accompanying drawings, which are incorporated in and constitute a part of this specification, illustrate various exemplary embodiments and together with the description, serve to explain the principles of the disclosed embodiments

FIG. 1 depicts an exemplary system for using machine-learning to model environments, in accordance with an aspect of the present disclosure.

FIG. 2 depicts an example of a method for using machine learning to model environments, in accordance with an aspect of the present disclosure.

FIG. 3 depicts an example of a method for using machine learning to model environments, in accordance with an aspect of the present disclosure.

FIGS. 4A and 4B depict example methods for providing or receiving adjustments to modeled environments, which may be used in conjunction with the methods of FIGS. 2 and 3.

FIG. 5 depicts an exemplary system for using machine-learning to model environments, in accordance with an aspect of the present disclosure.

FIG. 6 depicts an example application of a system for environmental modeling, in accordance with an aspect of the present disclosure.

FIG. 7 depicts a method for training a machine learning model, in accordance with an aspect.

FIG. 8 depicts an example of a computing device, in accordance with an aspect.

FIG. 9 depicts an exemplary report generated by the systems disclosed herein.

### DETAILED DESCRIPTION

Aspects of the present disclosure relate to improved modeling systems for environments or containers, such as ecosystems. As discussed herein, disclosed techniques employ machine learning in conjunction with modeling local constraints and influences, as provided by a local continuous model and a local discrete model, and modeling global (non-local) constraints or influences as provided by a global model. These techniques provide improvements relative to existing solutions.

Reference to any particular activity is provided in this disclosure only for convenience and not intended to limit the disclosure. A person of ordinary skill in the art would recognize that the concepts underlying the disclosed devices and methods may be utilized in any suitable activity. The disclosure may be understood with reference to the following description and the appended drawings, wherein like elements are referred to with the same reference numerals. The terminology used below may be interpreted in its broadest reasonable manner, even though it is being used in conjunction with a detailed description of certain specific examples of the present disclosure. Both the foregoing general description and the following detailed description are exemplary and explanatory only and are not restrictive of the features, as claimed.

In this disclosure, the term “based on” means “based at least in part on.” The singular forms “a,” “an,” and “the” include plural referents unless the context dictates otherwise. The term “exemplary” is used in the sense of “example” rather than “ideal.” The terms “comprises,” “comprising,” “includes,” “including,” or other variations thereof, are intended to cover a non-exclusive inclusion such that a process, method, or product that comprises a list of elements does not necessarily include only those elements, but may include other elements not expressly listed. The term “or” is used disjunctively, such that “at least one of A or B” includes, (A), (B), (A and A), (A and B), etc. Relative terms, such as, “substantially,” “approximately,” “about,” and “generally,” are used to indicate a possible variation of ±10% of a stated or understood value.

It will also be understood that, although ordinals (e.g., “first,” “second,” “third,” etc.) may be used herein for convenience to describe various elements, such terms are not limiting, and alternative ordinals may be used for a given element.

As used herein, the term “if” includes terms such as “when,” “upon,” “in response to determining,”or “in response to detecting,”depending on the context. Terms like “program,” “electronic application,” or the like, and generally encompasses software that is configured to interact with, modify, override, supplement, or operate in conjunction with other software.

The term “machine-learning model” generally encompasses instructions, data, or a model configured to receive input(s) and to apply one or more of a weight, bias, classification, or analysis on the input to generate an output. The output may include, for example, a classification of the input, an analysis based on the input, a prediction associated with the input, or any other suitable type of output. Training data is generally used to train a machine learning model. For example, experiential data or samples of input data are fed into the model in order to establish, tune, or modify one or more qualities of the model. For example, weights, biases, criteria for forming classifications or clusters, or the like may be established or adjusted using training data. Aspects of a machine-learning model may operate on an input via any suitable configuration (e.g., linearly, in parallel, or via a network (e.g., a neural network)). As a result of training, a machine-learning model is transitioned from an un-trained and unspecific model to a model that is unique to and specifically configured for the particular purpose for which it is trained. The result of training a machine-learning model using particular training data and for a particular purpose results in a technical solution to a technical problem.

The machine-learning model may utilize one or more machine learning techniques, such as random forest, gradient boosted machine (GBM), deep learning, a deep neural network, linear regression, or logistical regression. Supervised or unsupervised training may be utilized. For example, supervised learning may include providing training data and labels corresponding to the training data as ground truth. Unsupervised approaches may include clustering, classification, or the like. K-means clustering or K-Nearest Neighbors may also be used, which may be supervised or unsupervised. Combinations of K-Nearest Neighbors and an unsupervised cluster technique may also be used. Any suitable type of training may be used. Such training modalities may include stochastic, gradient boosted, random seeded, recursive, epoch or batch-based, etc.

Aspects of the present disclosure relate to improved modeling systems and methods for environments, such as ecosystems. As discussed above, existing environmental modeling solutions suffer from deficiencies. For instance, many conventional artificial intelligence systems involve a system obtain a measure, perform a computation on that measure, and produce a result, without modeling an entire environment. Another conventional approach involves using a recurrence, in which an output is added back to an input and the process is repeated, e.g., a transformer model. But this approach is dependent upon the computation being useful and correct, and is achieved by training the computation with data or a signal, e.g., via reinforcement learning. A computation is considered ready to implement when the training has in some sense converged. But this approach fails to capture any divergent process, in which a computation does not terminate or ends in an exceptional state and fails to continue to produce an action. For example, in biology there is no “end,” and biology continues to change and adapt into new forms. Similar to how biology evolves, a diverging computation can persist indefinitely, whether caused by an error or by its inherent nature as an infinite loop. The concept of divergence underscores the continuous evolution of biological systems and computational processes. This stands in contrast to a genetic algorithm, which aims to reach a local optimum within a fitness function.

Another conventional approach to modeling complex systems involves the system and agents being represented as (coupled) equations or as small algorithms. Broadly, existing agent-based modeling systems fall into two categories. A first set of existing systems include agents with a fixed task being orchestrated to most efficiently accomplish some larger goal, such as robots within a warehouse. A second set of systems include agents with low level behaviors in large numbers, such as ant colonies.

But these approaches fail to model global and local effects of the environment, and rarely capture agency of individual agents. For instance, systems may exist for modeling behavior of crabs. These models may in some cases be able to correctly predict crab population based on a number of crab eggs, but do not consider the inevitably dynamic environment in which the modeled entities are located.

Continuing the crab example, existing models may fail to consider the ocean as a whole, fish populations, predators, ocean temperatures, or fishing-all of which may affect the crab population. The relationships among the various factors above may be interdependent and may lead to downstream effects. These models fall short in cases such as when the crab population is invariably affected by the larger ecosystem. These models fail to account for the complex set of environmental and agent-based factors, including interrelationships among agents, that exist in real-life environments.

Disclosed solutions overcome these deficiencies. For example, in contrast to existing solutions, disclosed solutions provide improved agent-based modeling systems that accurately model entire environments or systems (e.g., ecosystems) by combining local and non-local (e.g., area or global) constraints or influences and combining discrete (discontinuous) and continuous (e.g., field-based) parameters. For example, disclosed systems combine global constraints, local behavior, and a non-smooth (e.g., non-continuous) action space in a container (e.g., an environment) that can be altered parametrically or counter factually.

Disclosed solutions model behavior of one or more agents such that the behavior of the agents is modulated by local fields, area (or global) fields, and discrete local algebraic factors. The fields are, for example, continuous vector fields. For instance, in the context of an ocean ecosystem, disclosed systems and methods enable ecosystem-based species management, including modeling of individual species that captures a chaotic, non-linear dynamic associated with the entire ocean, the contents of the ocean, and any applicable external forces. While ocean ecosystems are used as an example, disclosed solutions may also be used to model other systems. The disclosed systems and methods are not limited to ecosystems and also apply to modeling other environments or systems, such as economies.

The disclosed systems also incorporate aspects that allow for optimization or control of aspects of the modeled environment. For example, the system may make adjustments to parameters of the modeled environment in order to model effects of those adjustments. The adjustments may address or otherwise improve (e.g., optimize) issues with the agents or other aspects of the environment. For example, if the model indicates that the agents are behaving or will behave in an undesirable or sub-optimal manner, the system may adjust one or more parameters of the environment in order to affect the agent's behavior. Based on the modeling of the adjustments, the system may continue to make other adjustments or may choose an adjustment that results in the greatest improvement.

For example, the disclosed systems may include a plurality of models.

The system may include a plurality of agent models to model a plurality of agents. Each agent model may model a specific agent. Each agent of the plurality of agents may be a same type of agent (e.g., a same species or a same type of actor). Alternatively, different agent types may be modeled.

The system may also include a local continuous model. The local continuous model may model aspects of an environment that are localized (e.g., to one or more agents) and that have continuous properties. The local continuous model may be a field (e.g., vector field)-based model, in some examples.

The system may further include a local discrete model. The local discrete model may model aspects of an environment that are discrete (not continuous). For example, the local discrete model may model discontinuities, relationships (causal, correlation, ratios), or sequences. For example, discrete agent decision processes may be represented by Markov decision processes (MDP) in the local discrete model.

The model may further have a global continuous model that may model aspects of a larger environment that are continuous. The global continuous model may be a field-based (e.g., vector field) or other type of energy-based model. The field may be driven to a critical value, similar to an Ising field. The field may have a randomizing influence. Using the Ising model as an analogy, at higher “temperatures” (higher values of parameters of the field), locations within the field taking on random values is more likely. At lower temperatures (lower values of parameters of the field), locations within the field have less randomness. At a baseline temperature (e.g., a temperature of zero), there may be no randomness at all. In some examples, the local continuous model may also utilize a field similar to an Ising field having the principles above.

The global continuous model may thus act as an energy based model that constrains the agents. The local discrete model may act as a set of functions to be used by the agents. The local continuous model may be a gradient that is read from and written to, giving agency to the agents and a physics to areas (e.g., local areas).

The agents may range from simple mechanistic rule-response systems, to biologically realistic agents, to large, complex systems like governments.

An optimization or control module may be configured to adjust one or more inputs to one or more of the models in order to improve or otherwise alter agent behavior. For example, the optimization or control module may alter agent behavior directly or via adjusting parameters of the local continuous model, the local discrete model, or the global continuous model. The adjustments may be modeled according to the mechanisms described above in order to evaluate the adjustments.

The disclosed systems provide a tool that mixes global constraints, local behavior, and non-smooth action space in a container (e.g., an environment) that can be altered parametrically or counter-factually (e.g., by the optimization or control module) to report on or evaluate various scenarios. Any number of agents and agent types may interact with each other and their environment, and the systems capture micro to macro scale results in the agents and in the environment.

A method of using one or more of the disclosed systems may include the local continuous model constructing a vector. The vector may include callback indicators to the local continuous model (e.g., for values of the vector that are not constant, such as variables). The local continuous model may transmit a data package including the vector to the local discrete model. The local discrete model may add another vector, which may include callbacks to the local discrete model for non-constant values/variables, to the data package. The local discrete model may transmit the data package to the global continuous model. The global continuous model may add an additional vector, which may include callbacks to the global continuous model for non-constant values/variables, to the data package. The global continuous model may transmit the data package to an agent modeling system. The agent modeling system may include the plurality of agent models. Each of the agent models may utilize the data package, including the callbacks, to model a behavior of a modeled agent. The agent behavior may be provided to the local continuous model, and the above method may repeat. An optimization or control module may make one or more adjustments to the aspects modeled by any of the models above. The process above may repeat with the adjustments in order to model an altered system.

The systems and methods disclosed herein may be used to model emergent behavior, irrational agents, learning agents, and non-smooth changes (e.g., shocks) in any aspect (e.g., local environment or global environment). In some examples, each agent may be located in space (e.g., x, y, z coordinates) and in time (t). After a small change in time (delta t), each agent may update its location and update its own information (behavior). The models discussed above may also update based on the change in time. The models may update, at least in part, based on information about an agent's spatial (location) and temporal (time) parameters. In other examples, spatial parameters may not be used. For example, economic or other properties may be modeled for agents and updated over time. Such parameters may include, for example, gross domestic product (GDP), interest rates, monetary supply, investment, weather, consumer confidence, fads, trends, or news.

Below, non-limiting examples of aspects modeled by the disclosed systems and methods are described. These examples are intended to be illustrative and do not describe all possible applications of the disclosed systems and methods.

Furthermore, although certain parameters are provided as examples for what a particular module may model, those examples are exemplary only.

In one exemplary, non-limiting application of the system, the agents may include ships and animals, such as crabs and cod. Although a crab modeling system may be described below as an illustrative example, the disclosed systems encompass modeling various other environments or systems. The local continuous model may model a local habitat of the crabs. For example, the local continuous model may model a location of the ground, a location of the ice, or other relevant features of the local habitat. The local discrete model may model, for example, molting or predator-prey relationships. The global continuous model may model, for example, the price of crab, crab fishing laws, or other more global effects on the agents. The optimization or control module may adjust one or more of the aspects modeled by any of the models. For example, the optimization or control module may adjust one or more parameters and provide an input to an agent model system, which may generate a behavior based on inputs from one or more of the local continuous model, local discrete model, global continuous model, or optimization and control module.

In a further example, the disclosed systems may model illegal, unreported, and unregulated fishing (IUU). The local continuous model may model fish densities. The local discrete model may model effects of countries'laws and probabilities of those laws being enforced. The global continuous model may model demand for different fish. The agents modeled may be individual ships that go after fish. The agents (ships) may have different inclinations that may be modeled by different agent models or by different instantiations of the same agent model with different ground parameters. For example, some ships may be more inclined to follow rules or laws than other ships. The optimization or control module may simulate effects of changes in laws or may simulate how much change in rule-following behavior would be required by ships to achieve a certain (decreased) level of IUU.

In another non-limiting example, the disclosed systems and methods may model an economic environment or system. In such an example, the agents may be consumers or producers. The local continuous model may model, for example, supply. The local discrete model may model, for example, demand or productivity. The global continuous model may model market pressure. The optimization or control module may adjust one or more of the modeled aspects to provide an input to an agent model system modeling the agents.

In a further example, the disclosed systems and methods may model voting behavior. Agents modeled may be voters, such as voters having relationships with one another (e.g., members of a government or corporate body, such as Congress). The local continuous model may model a sentiment map of the voters (e.g., via a sentiment map). The local discrete model may model a graph for a voter. The global continuous model may model sentiment (e.g., more broadly).

In another example, the disclosed systems and methods may model a financial technology system. For example, a modeled agent may include a stock or other investment vehicle. The local continuous model may model stock prices. The local discrete model may include a graph computation that may be interpreted to understand stock price directions (increase or decreases).

In a further example, the disclosed systems and methods may model a power grid. Agents modeled may include power generators and consumers. The local continuous model may model a power grid. The local discrete model may model a graph (e.g., a physical network or arrangement) of power lines. The global continuous model may model power changes.

The examples described are described in further detail with respect to the Figures below.

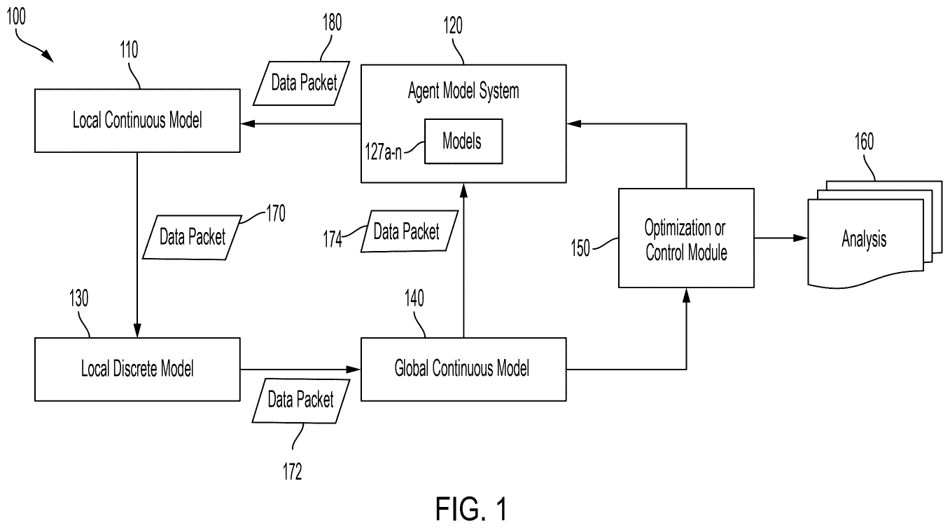

Turning now to the Figures, FIG. 1 depicts an exemplary system 100 for modeling environments, in accordance with one or more aspects of the present disclosure. For example, system 100 may use agent orchestration to model environments/systems. The word “environment,” as used herein, is not limited to habitats and includes other types of systems. In the example depicted, system 100 models an environment including one or more agents via agent model system 120 in conjunction with local constraints and influences, as provided by local continuous model 110, local discrete model 130, and non-local (e.g., area or global) constraints or influences, as provided by global continuous model 140. Optimization or control module 150 is configured to manage system 100 (e.g., to provide inputs to system 100) and to generating analysis 160. As explained below, the various functional modules of system 100 may use various techniques, such as machine learning. Although a certain flow of data is shown in FIG. 1 and described below, data may alternatively flow between different components of system 100 in different orders. The example provided below is merely illustrative.

Because the agents modeled by agent model system 120 are coupled by their environment, which feeds back to the agents, system 100 captures both micro and macro scale changes within the modeled environment. For example, system 100 can model any number of agent and agent classes, via agent model system 120, to interact both with each other and an environment, as modeled by local continuous model 110, local discrete model 130, and global continuous model 140. The scale, number of agents, and amount of time to simulate may be limited only by available computer power. Any of the models of agent model system 120, local continuous model 110, local discrete model 130, or global continuous model 140 may be machine learning models that are trained according to any of the techniques described above.

An agent may represent an entity. Examples of entities include, but are not limited to, fish, ships, economic actors, governments, and so forth. Agent model system 120 may model various actions by agents, including but not limited to, any actions the agents take or will take in the future. Any actions taken by agents may be in response to an external stimulus (e.g., rising water temperatures, changing prices, changes in interest rates, changing political temperatures, etc.) or in response to each other (e.g., a first organism moved closer to a second organism, and in response, the second organism moved away or a first economic actor engaged in a purchase that influenced a second economic actor).

To facilitate agent modeling, agent model system 120 may include one or more machine learning models 127a-n. Each machine learning model 127a-n may represent one or more groups or classes of agents. In an example, different groups of agents are modeled by separate machine learning models 127a-n. Each machine learning model 127a-n may be separately trained or instantiated. For instance, a particular machine learning model 127a-n may be trained for a particular class of agents. Each instantiation of an agent may have variations (to represent different individuals having different properties). For certain types of agents, such variations may be larger (e.g., agents with more complexity, decision-making ability, or individuality).

For other types of agents, such variations may be more slight/smaller (e.g., agents that are less complex, make fewer decisions, or have less individual variability).

Then, the trained model may be instantiated multiple times, for example, one instantiation per agent. The instantiations may have different parameters or weights, for instance, in a distribution. Thus, each individual agent within a class of agents may have its own instance of a machine learning model that has been trained or otherwise programmed to model a behavior of a class of agents to which the individual agent belongs.

A level of sophistication or complexity of a given agent machine learning model 127a-n may vary among types of agents or within a given type of agent. For instance, an agent could be modeled as a mechanistic rule-response system, a biologically realistic agent, or a large complex system like a government.

A behavior of any given agent may be at least partially dependent on one more external factors or other agents. Accordingly, agents may be configured to behave and interact with other agents and the environment. These interactions produce emergent effects that may differ from effects of individual agents. The disclosed systems facilitate modeling of observed data and also can be used to model the counterfactual or experiments that may be impossible or unethical to conduct. Agents may be modeled to have agency, for instance, an ability to make decisions and take actions. In some cases, certain agents may not be modeled at all, for instance, to reduce system complexity.

A level of agency of a given agent type (e.g., how complex an agent's decision-making process is) need not be proportional to a level of interest in modeling by a user of the system. For example, a modeling system may be focused on modeling behavior of crabs. The system therefore may use multiple instantiations of models, each model for a particular crab. But a crab may not have a high level of agency (the crab's decision-making may be relatively simple). By contrast, the system may also model ships as agents having a higher level of agency (the ships may make decisions in a more complex manner, based on more factors). For example the system can maintain information as to what a ship agent may do next. But the ships may be of less interest to an end user, but rather, are modeled for system completeness and their effect on the crab population.

Various events within the environment may be modeled. Any given event may affect one or more agents. An event may be detected by an agent, directly or indirectly. Examples in a crab model may include ocean temperatures and fishing trends. Events may be considered global, affecting an entire ecosystem, or local, affecting a local or limited area within the ecosystem.

System 100 involves not only agent modeling but agent orchestration, e.g., how agents coordinate with each other, to model an entire ecosystem. For example, system 100 can predict behavior of not just small entities such as the behavior of a crab located at the bottom of ocean, but also higher level behavior such as the predicted behavior of various schools of fish (e.g., salmon or carp). Continuing the example, system 100 may model, based on the fish and the crabs, one or more actions that fisherman may take. Additionally, system 100 can facilitate counterfactuals, such as the effect on the system of changes, such as a price of fish, the larger economy, and so forth. These capabilities enable new applications such as ecosystem-based fishery management.

As explained below, local continuous model 110, local discrete model 130, and global continuous model 140 collectively model an environment including any events. Each of local continuous model 110, local discrete model 130, and global continuous model 140 may generate a representation (e.g., a vector) that includes their respective environmental effects on the agents modeled by agent model system 120 or responses to queries, for example, based on time or position.

Further, each of the local continuous model 110, local discrete model 130, agent model system 120, global continuous model 140, or optimization or control module 150 may communicate with each other. As explained below, the models may pass data packets 170, 172, 174, 180, including vectors or other data forms among one other. For instance, various control signals, such as clock, coordinates, and so forth, may be passed between the models.

Local continuous model 110 is configurable to model local continuous aspects of an environment near an agent. The local continuous model 110 may be thought of as a “container” for an application of interest. Local continuous model 110 may be a field-based model. A local area may refer to a subset of the overall environment that is proximate to where one or more agents exist in a modeled space. For example, the proximity may be a physical proximity. Local continuous model 110 may model aspects of a local environment that are not discrete (not yes/no or on/off).

By way of example, flocking of birds would be modeled by local continuous model 110. In some examples, the local continuous model may be a gradient that is read from and written to and that gives agency to modeled agents and a physics to a local environment. For example, the local continuous model may model terrain features of a local environment (e.g., ice position, ground position, water properties), locations of other non-living entities, locations of entities that are living but do not have agency.

In some systems, the various agents modeled may be located in different local areas. Local continuous model 110 may model multiple local areas to account for different individual agents or different agent classes. In some examples, local continuous model 110 may include a plurality of models (although only one is shown for ease of illustration in FIG. 1), with one model for each local area being modeled.

Local continuous model may apply a function to obtain a value. As further explained below, local continuous model 110 may generate a data packet 170, which can include a vector with a plurality of components, which may be variables or constants. Although the term “vector” is used herein, it will be appreciated that data packet 170 or the other data packets disclosed herein may include a matrix or other collection of components. The components of vector(s) of data packet 170 may represent various aspects of the local environment modeled by local continuous model 110. For example, components of vector(s) of data packet 170 may include positions, times, velocities, accelerations, trends, equations, callback indicators, etc. The components of vector(s) of data packet 170 may be numerical or may be equations, cross-references, or callbacks. For example, vector(s) of data packet 170 may include one or more callback indicators to local continuous model 110. The callback may be utilized by other components of system 100 to obtain information from local continuous model 110 (e.g., for non-constant components of data packet 170).

Data packet 170 may then be provided to local discrete model 130 (or any other models, as appropriate). For example, local continuous model 110 may transmit data packet 170 having a vector generated by local continuous model 110 to local discrete model 130. When received, local discrete model 130 may utilize data (e.g., any of the components of vector(s)) from the data packet 170. For example, local discrete model 130 may use one or more of the components of vector(s) of data packet 170 as an input for local discrete model 130. Local discrete model 130 may make any callbacks as necessary to local continuous model 110 in order to obtain inputs for local discrete model 130.

Local discrete model 130 is configured to model factors that are local discrete effects on the agents. Local discrete effects or factors may be non-continuous or (yes/no or on/off). In examples, local discrete model 130 may model relationships (e.g., causal, correlation, ratios) and sequences. Examples of local discrete aspects include factors that influence an agent to take an action or not to take an action. Local discrete aspects may also include state to state transitions of an agent or another feature of the environment. For example, for a flock of birds, local discrete model 130 may model Markov decision processes (MDP). Local discrete model 130 may also model, for example, molting behaviors, predator-prey relationships, ships needing refueling, or certain states of fish.

In some systems, the various agents modeled may be located in different local areas. Local discrete model 130 may model multiple local areas to account for different individual agents or different agent classes. In some examples, local discrete model 130 may include a plurality of models (although only one is shown for ease of illustration in FIG. 1), with one model for each local area being modeled.

Local discrete model 130 may apply an operator that outputs another function. Local discrete model 130 generates an output such as a data packet 172. Data packet 172 may have any of the properties of data packet 170, except data packet 170 includes outputs (e.g., vector(s)) from local discrete model 130. For example, data packet 172 may include packet 170 and an output from local discrete model 130 (packet 170 may be merely passed through local discrete model 130). In some examples, data packet 172 includes a vector including the components of data packet 170. For example, data packet 172 may concatenate data output by local discrete model 130 with data from data packet 170. In other examples, a vector of data packet 172 generated by local discrete model 130 is a separate vector from the vector generated by local continuous model 110. As explained above for data packet 170, vector(s) of data packet 172 may include callback indicators to local discrete model 130, such that other models/systems may reference local discrete model 130 to obtain data. Local discrete model 130 may provide data packet 172 to another model, such as global continuous model 140, which may utilize data packet 172. In some examples, local discrete model 130 may combine vectors from local discrete model 130 and local continuous model 110 into a single vector. In other examples, data packet 172 may include separate vectors from local continuous model 110 and local discrete model 130.

Global continuous model 140 is configured to model one or more continuous global or systemic parameters. Global continuous model 140 may be an energy-based model. A global area may refer to a larger (e.g., overall environment) in which the agents exist (e.g., in the modeled space). The term “global” as used herein may include values that reflect the entire system/environment. For example, the term “global” may include a worldwide area but is not so limited and instead refers to an area that is larger than a local area. The effects may be continuous, rather than discrete.

Examples of global effects may include, depending on the environment being modeled, a price of fish, a price of gasoline, an amount of remaining fuel in a tank of a ship, fishing laws, macroeconomics, and a captain of a fishing ship.

In some examples, global continuous model 140 may operate using principles similar to Ising fields or Ising models. In an Ising model, a system behaves differently based on the system's temperature (as applied to continuous model 140, the temperature may be a literal temperature or a figurative “temperature”). When a system is on one side of a critical temperature (e.g., above the critical temperature), the system may be disordered and not demonstrate any field effects. However, when the system reaches or crosses the critical temperature (e.g., is below the critical temperature), the system may develop a field effect. In other words, when a “temperature” of the global field is high, many portions (e.g., locations) of the global field may take on random values. Increases in temperature are associated with increasing randomness. At lower temperatures, randomness is less likely. At a temperature of “zero” (at or below the critical value), there may be no randomness at all in the global field.

Global continuous model 140 may operate in various ways. In one example, global continuous model 140 may supply an energy map or value (an energy “reading”) to agent model system 120. In some examples, a temperature of global continuous model 140 may be set to a critical value. The acts of the agents of agent model system 120 may be correlated across the entire system/environment in such circumstances, such that any act of an agent will affect all other agents (the acts of agents are global in nature). In another example, a temperature of global continuous model 140 may not be fixed. In such circumstances, the acts of agents may sometimes be correlated across the entire system/environment (when the temperature is set to a critical value). At other times, the acts of the agents may not be correlated (when the temperature is not critical-e.g., when the temperature is above a critical value). In a further example, a temperature of global continuous model 140 may be set above the critical temperature. The agents may act so as to attempt to lower the energy (these attempts will fail if the temperature is pre-determined to remain above the critical temperature). Such a scenario allows users to obtain information about how agents handle a more random environment/system.

For example, a global (large-scale) environment may involve a large number of elements (which may have or may lack agency). At certain times, the elements may have vectors (which may be comprised of various components that affect the elements'behavior) that point in different directions. At such times, such elements would not exert a global field effect—the energy of the system/environment is higher. At other times, the elements may have vectors that are aligned. For example, such alignment may occur after the critical temperature (e.g., a zero temperature) is reached. For example, after a certain number of vectors are aligned, the rest may be come aligned. When the vectors of the elements are aligned, the elements may cause (e.g., exert) a collective global field effect.

By way of illustrative example, fishing captains (or ships) may be represented by a value of −1 if they are catching fish, and a value of +1 otherwise. At the beginning of a fishing season, fishing captains (the elements) may all have values of −1. The fishing captains may all be eager to begin their fishing season, may be stocked full of fuel, and may have fully staffed boats that are in a state of repair. As the season progresses, the shipping captains'vectors may begin to become misaligned, as some fishing captains'vectors switch to a +1 value as they stop fishing for various reasons (ships breaking down, running out of fuel, etc.). A value output by global continuous model may be a sum of the vectors of the fishing captains. The system may be at its optimum when the field has its lowest energy (all fishing captains have a vector of −1).

In another example, in modeling voting (e.g., voting of a cohort of individuals who know one another), local continuous model 110 may provide a two-dimensional matrix representing voter sentiment, which may be utilized by global continuous model 140. Continuous model 140 may utilize the matrix. Each location in the matrix may represent a set of values, and a value (e.g., vector) at a location may be a first political leaning or a second political leaning. The value (the first or second political leaning) may be assigned or determined using a critical temperature set. A location in the matrix may randomly switch political leanings; however, generally, a given location will try to be like its neighbors, to minimize energy in the system/environment. Global continuous model 140 may utilize aspects of a random field Ising model (RFIM). For example, political ads may be random fields that are applied to locations in the matrix provided by local continuous model 110.

Global continuous model 140 may utilize one or more of the components of vector(s) of data packet 172 as inputs. In some examples, global continuous model 140 may make callbacks to local continuous model 110 or local discrete model 130 in order to obtain necessary inputs for global continuous model 140. Global continuous model 140 may output a data packet 174, which may have any of the properties of data packets 170 and 172, except that data packet 174 may also include a vector that has components that reflect outputs from global continuous model 140. For example, data packet 174 may include information about time or spatial coordinates of effects from continuous model 140. In examples, continuous global model may output a vector having fields of [scalar, matrix, temperature]. The scalar may represent an energy, the matrix may represent a field, and the temperature may be a current field. In aspects, one or more of the data types above may be omitted.

Global continuous model 140 may apply an operator to output a matrix. Global continuous model 140 may package a vector output by global continuous model 140 along with a vectors output by local continuous model 110 and local discrete model 130 into data packet 174. In some examples, global continuous model 140 may combine vectors from local continuous model 110, local discrete model 130, and global continuous model 140 into a single vector. Alternatively, the vectors from local continuous model 110, local discrete model 130, and global continuous model 140 may remain as separate vectors in data packet 172. Global continuous model 140 may provide data packet 174 to agent model system 120 (or any other models, as appropriate). Global continuous model 140 may also provide data packet 174 (or another data packet) to optimization or control module 150, as described below.

Agent model system 120 may use data from data packet 174 as inputs for models 127a-n. Agent model system 120 may make callbacks to any or all of local continuous model 110, local discrete model 130, or global continuous model 140. For example, agent model system 120 may make callbacks based on indicators in data packet 174 that such callbacks should be made. Agent model system 120, as discussed above, may include a models 127a-n. Each agent may have an instance of one of models 127a-n. The agent model system 120 may model behavior of each individual agent. For example, agent model system 120 may model movements over time, spending behavior, decision-making, or any other type of behavior of the agents.

For example, a model 127a-n of agent model system 120 may take an output from local continuous model 110 and callback to local discrete model 130 using an agent state (which may be stored by model 127a-n) to find the agent's next (probable) state. For example, an agent bird may have an agent state of being on the ground, and local continuous model 110 may provide an output indicating that one or more other birds (e.g., a bird with a special relationship, such as a parent-child relationship to the agent bird) are in the air. The model 127a-n of agent model system 120 may make a callback to local discrete model 130, which may supply a rule that governs the agent bird's behavior. The actual state of the agent bird (e.g., on the ground) may be input to the rule of local discrete model 130, such that the model 127a-n of the agent model system 120 determines that the agent's next state is to take off.

In another example, a model 127a-n of agent model system 120 may model behavior of a car buying agent. Local continuous model 110 may output information about all cars for sale. Model 127a-n may store information about the agent (e.g., how skilled the agent is at negotiating and the price the agent is willing to pay).

Model 127a-n may make a callback to local discrete model 130 and may input the information about the agent into a rule provided by local discrete model 130 to obtain a prediction about the agent's next behavior.

In yet another example, a model 127a-n of agent model system 120 may model behavior of a voter. Local continuous model 110 may supply a map of behavior of other voters (e.g., a map of other voters'inclination or determination to vote a first way or a second way). Global continuous model may supply a “temperature” of the political landscape/environment. Model 127a-n may make a callback to local discrete model 130 and may provide inputs (e.g., a location on a political map of the particular agent or inputs from local continuous model 110 or global continuous model 140) to a rule provided by local discrete model 130 in order to predict a behavior of the agent.

Outputs from agent model system 120 system may be provided to local continuous model 110, and the steps above may be repeated (iterated) any suitable number of times. For example, agent model system 120 may output a data packet 180 that describes one or more behaviors of the agent. For example, data packet 180 may include one or more vectors. Data packet 180 may include, for example, a vector including spatial information (e.g., coordinates), time, movement trajectories, food consumption, death (a mass of a body may be added to the environment as food), voting decisions, purchase decisions, or any other components representing modeled behaviors and decision-making. In some examples, the data packet 180 may include vector(s) or other data structures having components that reflect the behavior of individual agents.

Data packet 180 may not include data from data packets 170, 172, or 174. In other examples, data packet 180 may include vector(s) or other data structures reflecting collective behavior of agents as a class. Although the singular term “vector” is used, it will be appreciated that multiple vectors may be output by any of the models described above. For example, agent model system 120 may output a vector for each class of agents modeled. The other models may output a corresponding number of vectors or may synthesize the plurality of vectors output by agent model system 120 into a single vector. Local continuous model 110 may use data packet 180 provided by agent model system 120 as an input.

In some cases, the various functional modules may update on a periodic basis, for example, based on a clock signal. The clock signal may be generated by system 100, or generated by an external source and received into system 100. For example, each of local continuous model 110, local discrete model 130, global continuous model 140, agent model system 120, and optimization or control module 150 (discussed below) may operate and provide an output for a first given time, t=1.

The models may then operate and provide a further output for a second, later time, t=2, and so on.

Global continuous model 140 may, in some instances (e.g., after a certain number of times of iterating the data flow described above, during each iteration of the data flow, or at other times that may be predetermined), provide data packet 174 (or another data packet) to optimization or control module 150. Optimization or control module 150 is configured to control the other functional modules or to combine outputs from the modules. Although optimization or control module 150 is depicted as one module, optimization or control module 150 may alternatively include two or more modules.

For example, optimization or control module 150 may provide inputs to agent model system 120 to simulate changes (e.g., counterfactuals) to the environment. For example, optimization or control module 150 may allow simulation of proposed interventions to the environment in order to modulate behaviors of agents. In some examples, counterfactuals generated by optimization or control module 150 may be generated in order to optimize one or more aspects of the environment modeled by system 100.

In some examples, optimization or control module 150 may provide an output (e.g., a vector) that is a control field. The control field may be similar to the fields of global continuous model 140. For example, a control field may be applied to the Ising-like field output by global continuous model 140. In other words, the control field of optimization or control field may modulate the field of global continuous field. In alternatives, optimization or control module 150 may alter parameters of the modeled environment in other ways. For example, optimization or control agent model system 120 may use the output of optimization or control module 150 as an input.

In an example, a modeled system may be optimized based on energy level. In some examples, each agent may have a corresponding local and global field, provided by local continuous model 110 and global continuous model 140. Optimization or control module 150 may generate a field or other output that adjusts agent parameters (e.g., a level of agency), so the system moves in a direction of lower energy.

For example, optimization or control module 150 may generate an energy surface that facilitates an optimization by enabling a gradient descent on the energy surface. Optimization or control module 150 may use field(s) from global continuous model 140 as inputs. The energy surface may be used to perform optimizations. For example, system 100 may move in a direction of lower energy. By way of an illustrative example, if a ship being in port represents a high energy level and a ship catching fish represents a low energy level, then the parameters of system 100 may be optimized for lower energy level, i.e., ships catching fish.

Operation or control module 150 may provide an output (e.g., a data packet) to agent model system 120. In some examples, a data packet output by operation or control module 150 may be similar to data packets 170, 172, 174 and may include some or all of the data of data packets 170, 172, 174. Alternatively, a data packet output by operation or control module 150 may lack data from data packets 170, 172, 174 and may be separate from those data packets.

Agent model system 120 may utilize the output from operation or control module 150, similarly to how agent model system 120 may utilize the data from local continuous model 110, local discrete model 130, or global continuous model 140, as described above.

Optimization or control module 150 is also configured to generate analysis 160. Analysis 160 may incorporate modeling using any control field output as described above. In such examples, analysis 160 may include an analysis of proposed interventions to be made to the modeled environment. In other examples, analysis 160 may relate to an existing state of the modeled environment, rather than proposed interventions. Analysis 160 may have any suitable format. For example, analysis 160 may include textual reports or graphical representations. In some examples, analysis 160 may include animations that depict behaviors of modeled agents.

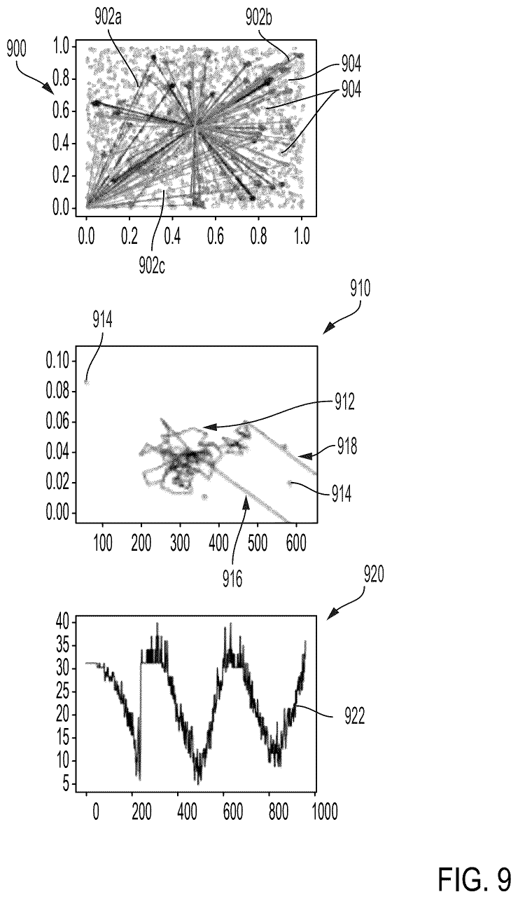

FIG. 9 shows exemplary reports or portions of reports that may be output by operation or control module 150. The reports described herein may be portions of a user interface displayed to a user on a screen. The reports may include textual information, in addition to the graphical information depicted. A first report 900 may be a habitat map. For example, report 900 may show trajectories (e.g., lines or curves) 902a, 902b, 902c for respective agents. Although three trajectories 902a, 902b, 902c are labeled for convenience report 900 shows many more trajectories. Report 900 may also show a plurality of locations 904 that are from a list of each agent's favorite locations (e.g., a list of prior locations for each agent). Locations 904 may be represented by dots, although such a representation is merely exemplary. Starting and ending points of each trajectory 902a, 902b, 902c may also be represented by dots.

In some examples, locations 904 may be dots of a first color, and each trajectory 902a, 902b, 902c may be represented by another color. In some examples, each trajectory 902a, 902b, 902c may have a unique color. In other examples, trajectories 902a, 902b, 902c having common properties may share a color. In some examples, locations 904 may be represented by a plurality of colors (e.g., a different color for each agent).

Display 910 may show motion (e.g., Brownian motion) of a single agent. In some examples, display 910 may be a magnification of aspects of report 900. An agent's trajectory 912 may cluster around a favorite location (e.g., one of locations 904). Trajectory 912 may also show a trajectory 916 traveling to the favorite location and a trajectory 918 traveling from the favorite location. Display 910 may also depict locations 914, which may be a subset of locations 914. For example, locations 914 may all be associated with the agent having trajectory 912 (e.g., past locations of the agent) or may be associated with different agents.

Display 920 shows a graph 922 of the energy of the modeled environment/system. For example, lower energy values may represent when fishing in a crab model is high, and higher energy values may represent when ships are in port in the crab model. Graph 922 of display 920 may show energy levels over 1,000 time steps (e.g., 1,000 iterations of running system 100). The X-axis may show the number of time steps, and the Y-axis may show the energy level.

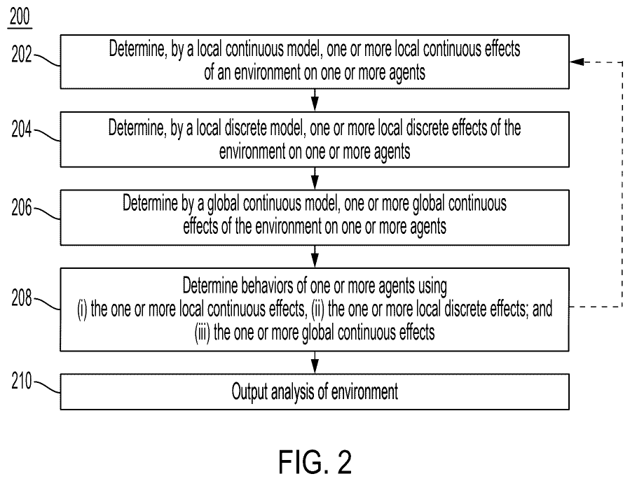

FIG. 2 depicts an example of a method 200 for using machine learning to model environments, in accordance with an aspect of the present disclosure. For illustrative purposes, method 200 is discussed with respect to system 100. However, method 200 could be applied to other systems. Further, while method 200 depicts various operations, not all the operations listed may be performed or some operations may be repeated as appropriate.

At step 202, method 200 may involve determining (e.g., modeling), by local continuous model 110, one or more local continuous aspects of a local environment. For example, step 202 may include determining local continuous effects on one or more modeled agents or one or more classes of modeled agents. The effects may include any of the aspects of local continuous model 110 discussed above. The one or more local continuous effects may relate to a local area proximate to one or more of the agents and are continuous (not discrete) in nature.

For example, step 202 may include supplying one or more inputs to a machine learning model that has been trained to model continuous aspects of a local environment. The machine learning model may apply one or more parameters or weights to the input. Following completion of modeling by local continuous model 110, local continuous model 110 generates data packet 170 and provides data packet 170 (which may include a vector, as described above) to the local discrete model 130.

At step 204, method 200 may involve determining, by local discrete model 130, one or more local discrete aspects of the environment. For example, step 204 may include modeling one or more local discrete effects on the modeled agents or classes of agents. The local discrete effects may include any of the local discrete effects discussed above. Local discrete model 130 may model various local discrete effects that relate to the local area of an environment or system and are discrete in nature.

In some examples, step 204 may include applying a trained machine learning model to one or more inputs, which may include components of vector(s) of data packet 170. Local discrete model 130 may employ one or more equations (e.g., algebraic equations) to the inputs to local discrete model 130. In some examples, based on indications (e.g., callbacks) in data packet 170, local discrete model 130 may reference local continuous model 110 (make a callback to local continuous model 110). Following completion of modeling, local discrete model 130 may generate data packet 172. As discussed above, data packet 172 may include separate vectors from local continuous model 110 and local discrete model 130. Alternatively, data packet may combine vectors from local continuous model 110 and local discrete model 130 into a single vector or matrix. Local discrete model 130 may provide data packet 172 to continuous model 140.

At step 206, method 200 may involve determining, by global continuous model 140, one or more global continuous aspects of the environment of the agents.

Global continuous model 140 may use as inputs, for example, data from data packet 172. Global continuous model 140 may, in some examples, make callbacks to local continuous model 110 or local discrete model 130 based on indicators (e.g., callback indicators) in data packet 172.

In examples, global continuous model 140 may apply one or more global fields (e.g., using principles similar to Ising fields, as described above). The one or more global continuous aspects relate to the larger environment (a larger environment than the local continuous model 110 and the local discrete model 130) and are continuous in nature. Following completion of modeling, global continuous model 140 generates data packet 174. Global continuous model 140 may transmit data packet 174 to agent model system 120. In some examples, data packet 174 may incorporate vector(s) from data packet 172. In some examples, vectors from each of local continuous model 110, local discrete model 130, and global continuous model 140 may remain as separate vectors in data packet 174. Alternatively, vectors from local continuous model 110, local discrete model 130, and global continuous model 140 may be combined or may be elements of a matrix comprising all of the vectors. Data packet 174 transmitted by continuous model 140 may include all of the data of data packets 170, 172.

At step 208, method 200 may involve determining, via agent model system 120 (including one or more machine learning models) one or more behaviors of the one or more modeled agents. Agent model system 120 uses one or more models 127a-n to model behavior of the agents in response to information received in data packets 170, 172, or 174, as described above.

More specifically, model system 120 provides, to one or more of the models 127a-n, the one or more local continuous aspects, the one or more local discrete aspects, or the one or more global continuous aspects. In some examples, models 127a-n may make callbacks to an appropriate model of local continuous model 110, local discrete model 130, or global continuous model 140 (e.g., based on callback indicators in data packets 170, 172, or 174). The one or more models 127a-n generate a representation of one or more behaviors of the agents in response to the various effects.

The effects represented in data packets 170, 172, or 174 may affect or more of the agents modeled by agent model system 120. For example, the agent models 127a-n may receive information from the world around the agent (e.g., data packet 174), encode its input, and utilize past and present information about a respective agent, thereby modeling an intent of the agent. The intent may become a plan, which may result in actions by the agent. The agents may exhibit certain behaviors. For example, the modeled agents may take a decision or perform an action such as relocating or otherwise moving, fighting, reproducing, eating, molting, fishing, going to port, going to a destination, unloading, refueling, buying, selling, consuming producing, voting, etc. The types of behaviors or actions taken by an agent may be dependent on the type of agent and the context of system 100.

In some examples, as represented by the broken arrow in FIG. 2, agent model system 120 may provide data packet 180 including a representation of the behaviors to local continuous model 110, which in turn generates an environmental reaction and repeats step 202 The other steps of method 200 may also be repeated/iterated. Thus, system 100 may model not only effects of an environment on an agent but also effects of the agent on the environment (and, in turn, the effects that the altered environment may have on the agents). Method 200 may be iterated any suitable number of times.

At step 210, method 200 may involve outputting analysis 160 of the environment. For example, optimization or control module 150 may generate one or more reports regarding the environment. Analysis 160 may have any of the properties described above. In some examples, step 210 may include generating and outputting a computer display to reflect aspects of the environment, as described above.

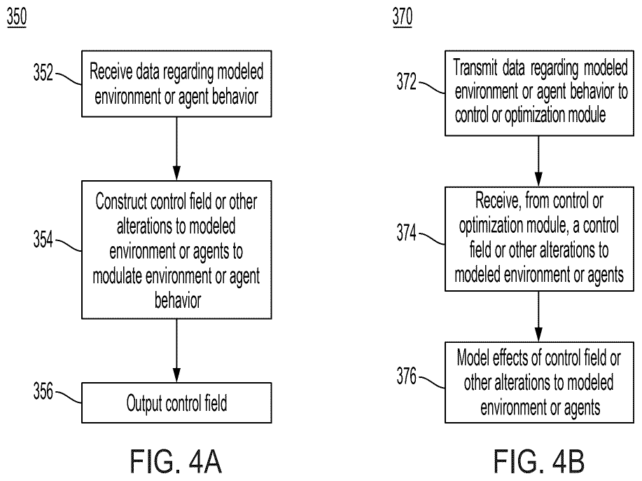

In some cases, optimization or control module 150 may generate or provide inputs (e.g., a control field or other alteration, such as a counterfactual alteration, to the environment). More details about the inputs provided by optimization or control module 150 are discussed below, with respect to FIGS. 4A and 4B.

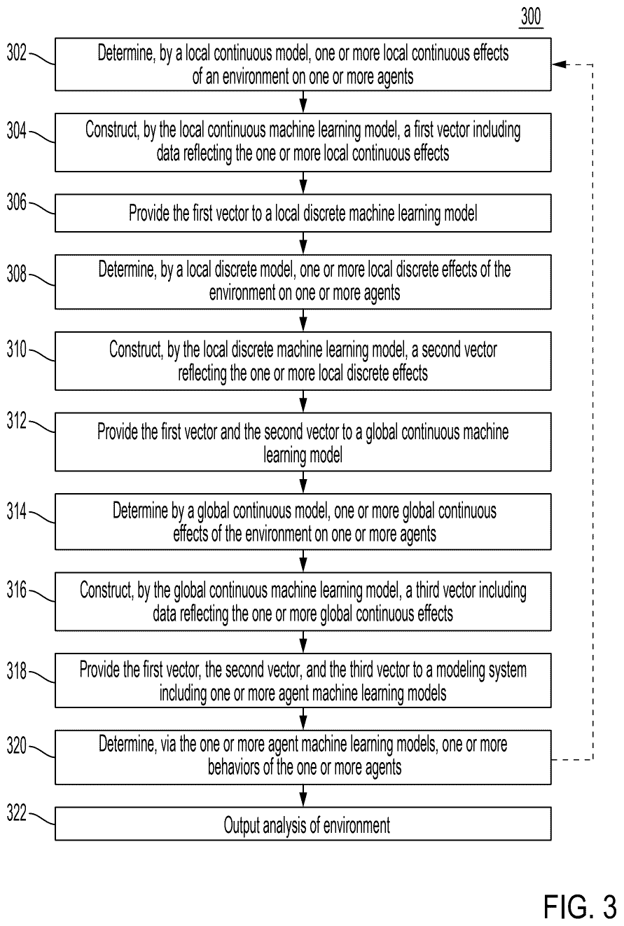

FIG. 3 depicts an example of a method 300 for using machine learning to model environments, in accordance with an aspect of the present disclosure. Relative to method 200, method 300 provides additional optional implementation details.

For illustrative purposes, method 300 is discussed with respect to system 100. However, method 300 could be applied to other systems. Further, while method 300 depicts various operations, not all the operations listed may be performed or some operations may be repeated as appropriate.

At step 302, method 300 may involve determining, by a local continuous machine learning model, one or more local continuous aspects of an environment that is local to one or more of the agents. Step 302 may involve any of the aspects of step 202, described above. The one or more local continuous aspects relate to a local area proximate to one or more of the agents and are continuous in nature. At step 302, method 300 involves performing substantially similar operations as discussed with respect to step 202. For example, local continuous model 110 may include one or more machine learning models, e.g., a local continuous machine learning model, trained to predict the local continuous aspects.

At step 304, method 300 may involve constructing, by the local continuous machine learning model, a first vector including data reflecting the one or more local continuous aspects. For example, following completion of modeling, local continuous model 110 generates a first vector.

At step 306, method 300 may involve providing the first vector to a local discrete machine learning model via, for example, data packet 170. Continuing the example, local discrete model 130 provides the first vector to the local discrete model 130. In some cases, the first vector may include one or more callback indicators, e.g., references, to the local continuous model 110. In this manner, the local discrete model 130 may query the local continuous model 110, without a need for the first vector to include large amounts of data. Furthermore, local discrete model 130 may query local continuous model for information that changes over time (non-constant information).

At step 308, method 300 may involve determining, by the local discrete machine learning model, one or more local discrete aspects of the environment. The one or more local discrete aspects relate to the local area and are discrete in nature. At step 308, method 300 involves performing substantially similar operations as discussed with respect to step 204. For example, local discrete model 130 may include one or more machine learning models, e.g., a local discrete machine learning model, trained to predict the local discrete aspects.

At step 310, method 300 may involve constructing, by local discrete model 130, a second vector reflecting the one or more local discrete aspects. As discussed above, in some examples, the second vector may be a separate vector from the first vector (from local continuous model 110) or, alternatively, the second vector may be combined with the first vector into a same vector or, for example, into a matrix.

In some cases, the second vector may include one or more callback indicators, e.g., references, to local discrete model 130 (or local discrete model 130, if the second vector includes the data of the first vector). In this manner, the global continuous model 140 or other downstream modules may query local continuous model 110 or local discrete model 130, without a need for the vector to include large amounts of data. Furthermore, the callback indicators or references may permit updating of non-constant information by the relevant model that generated the vector.

At step 312, method 300 may involve providing the second vector to a global continuous machine learning model. Global continuous model 140 may include one or more machine learning models, e.g., a global continuous machine learning model, trained to predict the global continuous aspects. Although step 312 also lists providing the first vector, it will be appreciated that such a step may be omitted if the second vector is combined with the first vector.

At step 314, method 300 may involve determining, by global continuous model 140, one or more global continuous aspects of the larger environment. The one or more global continuous aspects relate to the environment and are continuous in nature. At step 314, method 300 involves performing substantially similar operations as discussed with respect to step 206.

At step 316, method 300 may involve constructing, by global continuous model 140, a third vector reflecting the one or more global continuous aspects. As discussed above, the third vector may include the data of the first vector and the second vector (e.g., as a combined vector or as, for example, a matrix). Alternatively, the first, second, and third vectors may remain as separate vectors. In some cases, the third vector may include one or more callback indicators, e.g., references, to global continuous model 140 (or local continuous model 110 or local discrete model 130, if the vectors are combined).

At step 318, method 300 may involve providing the third vector to modeling system 120 including one or more agent machine learning models 127a-n. Each of the one or more agent machine learning models 127a-n is associated with a respective agent or class of agent of the one or more agents. Although step 318 in FIG. 3 also describes providing the first vector and the second vector, it will be appreciated that only the third vector may be provided if the third vector includes the data of the first vector and the second vector. For example, the third vector may concatenate the data from global continuous model 140 with the first and second vectors.

At step 320, method 300 may involve determining, via one or more agent machine learning models 127a-n, one or more behaviors of the one or more agents, a representation of the one or more behaviors. At step 320, method 300 involves performing substantially similar operations as discussed with respect to step 208 of method 200. The one or more models 127a-n obtain, from the first vector, the second vector, or the third vector, as appropriate, the local continuous aspects, the local discrete aspects, and the global continuous aspects. In an example, model 127a models a first set of agents, whereas model 127b models a second set of agents, and so forth. Multiple instances of each model may run to model individual agents of a given class. In some cases, accessing the first, second, or third vectors includes making callbacks to the local continuous machine learning model, the local discrete machine learning model, or the global continuous machine learning model.

As shown in FIG. 3, steps 302, 304, 306, 308, 310, 314, 316, 318, and 320 may be repeated. As discussed above, the steps may be repeated any suitable number of times (e.g., a set number of times or until a predetermined condition is satisfied).

At step 322, method 300 may involve outputting analysis 160 of the environment. For example, optimization or control module 150 may generate one or more reports regarding the environment. Analysis 160 may have any of the properties described above. In some examples, step 210 may include generating and outputting a computer display to reflect aspects of the environment, as described above.

In some cases, optimization or control module 150 may generate or provide inputs (e.g., a control field or other alteration, such as a counterfactual alteration, to the environment). More details about the inputs provided by optimization or control module 150 are discussed below, with respect to FIGS. 4A and 4B.

FIGS. 4A and 4B depict exemplary methods 350 and 370 for operation of optimization or control module 150. Methods 350 and 370 may be combined with methods 200 and 300. For example, methods 350 and 370 may occur between steps 316 and 318 of method 300 or between steps 206 and 208 of method 200.

In step 352, optimization or control module 150 may receive data regarding a modeled environment or behavior of one or more agents. For example, optimization or control module may receive data from global continuous model 140.

However, optimization or control module 150 may alternatively receive data from other components of system 100. In some examples, data received in step 352 may include data regarding agent behavior. In other examples, the data received in step 352 may lack data regarding agent behavior (e.g., because models 127a-n of agent model system 120 have not yet operated).

In step 354, the optimization or control module 150 may construct a control field or other alternations to the modeled environment or to the agents. Although the term “control field” is used for convenience in FIG. 4A, it will be appreciated that optimization or control module 150 may create alternative types of data structures. The control field or other alterations may modulate the environment or the agent behavior. In some examples, a control field may be somewhat similar to the global fields analyzed by global continuous model 140. The control field may control what agents perceive or experience and how they formulate intents and actions based on what they perceive. The control field may also modulate aspects about an agent (e.g., an agent's skills-such as negotiation or probability of catching food). The control field may also model a sudden death event of agents by setting at least some agents'ages to be greater than the agents'life expectancy.

The control field may, in some examples, modulate a field modeled by global continuous model 140. Alternatively, the control field or other control data provided by optimization or control module 150 may modulate aspects modeled by local continuous model 110 or local discrete model 130. In some examples, optimization or control module 150 may provide other, alternative types of outputs. For example, optimization or control module 150 may construct vector(s) (e.g., separate vectors from those described above). Alternatively, optimization or control module 150 may alter one of the vectors generated by local continuous model 110, local discrete model 130, or global continuous model 140.

In step 356, optimization or control module 150 may output the control field or other type of output (e.g., vectors). In some examples, optimization or control module 150 may output the control field or other data to agent model system 120. Agent model system 120 may make use of the data output by optimization or control module 150, as well as the various data packets (and vectors) described above. In alternatives, optimization or control module 150 may output the control field or other type of data to another module of system 100 (e.g., one of the models).

The data output by optimization or control module may represent a hypothetical adjustment to the modeled environment. For example, a user or an element of system 100 may determine that it is desirable to model certain changes to the modeled environment. For example, the modulation provided in step 356 may reflect expected future properties of an environment (e.g., due to one or more expected changes to the environment). In alternatives, the modulation provided in step 356 may reflect proposed interventions to be made (e.g., by humans or machines controlled by humans) to the environment. For example, where behavior of an agent is sub-optimal, intervention may be contemplated in order to produce different agent behavior. The output of optimization or control module 150 may allow counterfactual simulations of such interventions or such expected natural developments in an environment.

During operation of model (e.g., during methods 200 or 300), method 350 may be performed zero times, one time, or more than one time. For example, after the output of step 356 is modeled by one or more of the models of system 100, the optimization or control module may produce alternative (e.g., iteratively alternative) outputs to simulate different changes to the environment modeled by system 100.

FIG. 4B depicts a method 370 having steps that are similar to those of method 350, except from the perspective of other elements of system 100. In step 372, data may be transmitted to, for example, optimization or control module 150. For example, the data transmitted may reflect a modeled environment or agent behavior. In some examples, step 372 may be performed by global continuous model, as depicted in FIG. 1. However, other components of system 100 may alternatively provide the data to control or operation module 150. The data may include any of the vectors and data packets described above.

In step 374, an element of system 100 may receive, from optimization or control module 150, a control field or other alterations to the modeled environment or agents. The control field or alterations may have any of the properties described above. In some examples, agent model system 120 may receive the control field or other alterations. However, other component of system 100 may alternatively receive the control field or other alterations.

In step 376, one or more elements of system 100 may model effects of the control field or other alterations to the modeled environment or agents. For example, agent model system 120 may use the control field or other alterations as an input and may model agent behavior accounting for the control field or other alterations. As described above, the agent model system may provide a data packet to local continuous model 110, which may perform any of the operations described above.

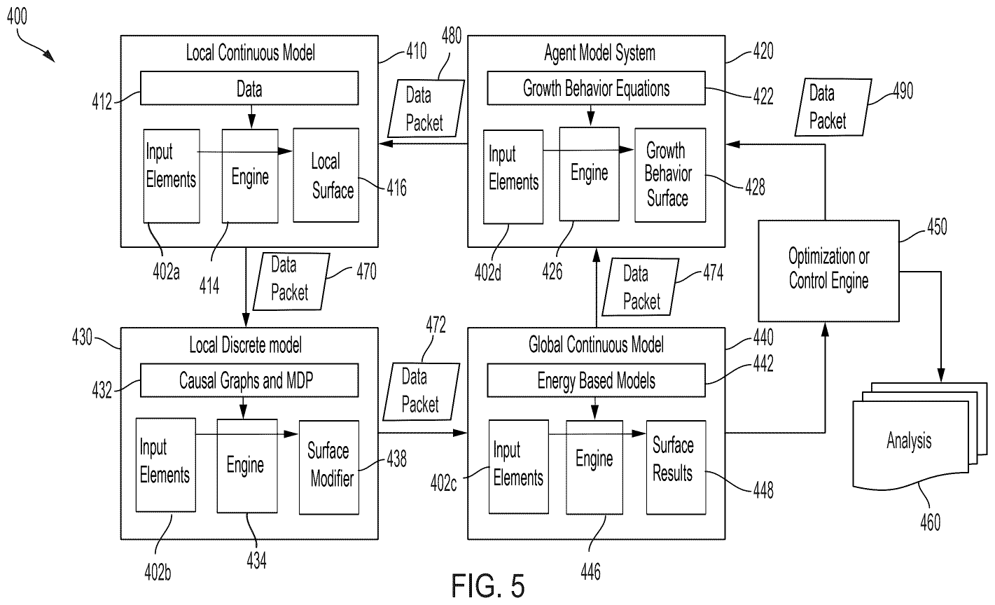

FIG. 5 depicts an exemplary system 400 for using machine-learning to model environments, in accordance with an aspect of the present disclosure. FIG. 5 depicts a local continuous model 410, a local discrete model 430, an agent model system 420, a global continuous model 440, an optimization or control module 450, and analysis 460. System 400 illustrates further detail and exemplary use cases relative to system 100 depicted in FIG. 1. Unless otherwise specified, system 400 may have any of the properties of system 100. Where feasible, reference numbers of system 400 add 300 to reference numbers of system 100 in order to indicate analogous elements.

In the example depicted in FIG. 5, system 400 models one or more agents via agent model system 420 in conjunction with local constraints and influences, as provided by local continuous model 410, local discrete model 430, and non-local (e.g., area or global) constraints or influences, as provided by global continuous model 440. As explained below, one or more of the components below may employ modeling such as Bayesian models, classifiers, machine learning models, and so forth, in addition to various mathematical functions, variables, or constants.

In some cases, one or more elements of system 400 generate, based on their respective models, a representation of one or more environmental aspects or agent behaviors related to a particular point in time and space.

Herein, positions may be described and may be represented by coordinates in one, two, or three dimensions. Time may be on an absolute or relative scale. Although positions and times may be referenced herein, it will be appreciated that system 400 may model environments (e.g., economies or other types of complex systems) based on elements other than positional coordinates, as described in further detail below.

In some aspects, system 400 may operate on a periodic, or clock-driven basis. For example, each of local continuous model 410, local discrete model 430, and global continuous model 440 may each calculate their respective effects at increments of time (for example, at t, (t+1), (t+2), etc.) The modeled agents may be updated by reading information from the other functional blocks for a given time value. Each iteration of methods 200 or 300 may model a single time. For example, data may flow from local continuous model 410 to local discrete model 430, to global continuous model 440, to optimization or control module 450, and to agent model system 420 once for each time instance that is modeled. System 100 may operate in a similar manner.

Local continuous model 410 is configured to model local continuous aspects, as discussed with respect to local continuous model 110. Local continuous model 410 may model continuous aspects of an overall habitat of the area in which the agents are located. In an example, continuous aspects of the habitat include structure, a location of the ground, a location of ice, a location of water, and so forth. Local continuous model 410 may also model behaviors such as flocking, which are continuous.

In an example, local continuous model 410 may utilize input elements 402a, which may be, for example, position and time coordinates. In some examples, input elements 402a may include data received from agent model system 420 (e.g., via a data packet 480, having any of the properties of data packet 180). Local continuous model 410 may also receive other data 412. For example, in a fishing model, data 412 may include a world model of ocean currents and may store a map for a time step prior to the time being modeled as a two-dimensional matrix of a surface of the ocean. Each cell of the matrix may contain a vector giving the direction and magnitude of a current at that location.

Using an engine 414, which may include one or more machine learning models, local continuous model 410 may generate a local surface 416, which may represent one or more local continuous aspects. Local surface 416 may operate like a function. Engine 414 may be a physics engine that, for example, estimates future ocean currents based on current ocean currents for a certain amount of time change. One exemplary, not limiting algorithm, is an upwind differencing scheme for convection. In some examples, the local surface 416 may be reflected in a vector (such as the vector discussed with respect to local continuous model 110 and method step 304. However, alternative data formats may be utilized. The vector or other data format may include one or more callback indicators so that other elements of system 400 may reference (e.g., query) local continuous model 410. The vector or other data format may be packaged in data packet 470.

Engine 414 can include various mathematical function such as interpolation functions, equations, and so forth. For instance, for any given point on an ocean surface, if the temperature at the surface and a temperature at first point at depth are modeled, then obtaining a temperature at a point between the surface and the first point may require interpolation. Engine 414 may further include models such as machine learning models, classifiers, or Bayesian models.

Engine 414 may include a local continuous machine learning model to determine, based on the data 412, one or more local continuous aspects. In turn, local continuous model may generate data packet 470, which can represent or refer to data structures (e.g., via callbacks) that represent such effects.

For example, data packet 470 may include a callback to input elements 402a. An agent model of agent model system 420 may seek information about the ocean current that the agent is located in. Continuing with an exemplary fishing or crab model, the agent model of agent model system 420 may pass a current time “t” and an agent's current location and call input elements 402a. Input elements 402a may pass along the time “t” and the agent's current location to engine 414, which may compute a new ocean current model for time “t” and return to agent model system 420 a single vector of a single cell of that map for the location of the agent. If other agent models of agent model system 420 also call back to local continuous model 410, because the ocean map is now current at time “t,” the map will not need to be rebuilt. If no agent model of agent model system 420 calls back for an ocean current value, no map will be constructed. Numerous callbacks may be made.

Local discrete model 430 is configured to model factors that are local discrete effects on the agents. Local discrete model 430 may have any of the properties of local discrete model 130. Local discrete model 430 may model factors that change between states, e.g. from a first state to a second state, discontinuities, relationships (e.g., causal, correlation, ratios), and sequences. One example of a local discrete decision is the kettling of birds. In this example, the modeled birds make a discrete choice of whether to take flight together, based on local information available to the model. For example, the system may model attempt by birds to avoid colliding with each other. Other examples of local discrete aspects include predator-prey relationships and a decision of a captain of a ship to return to port or to stay and fish.

In an example, local discrete model 430 receives data packet 470 from the local continuous model 410 and in turn generates data packet 472, which can represent or refer to data structures (e.g., via callback indicators) that represent such effects. Data packets 470 and 472 may have any of the properties of data packets 170 and 172, respectively.

In an example, local discrete model 430 may utilize input elements 402b, which may include, for example, position and time coordinates. In some examples, input elements 402b may include data received in data packet 470 (which may include data from data packet 480). An engine 434 may utilize input elements 402b, as well as inputs from causal graphs and a function library 432 to generate a surface modifier 438. Causal graphs and function library 432 may store various mathematical equations and relationships (including, but not limited to, causal graphs and MDP tools). In some examples, engine 434 may include a neural network classifier, although such an example is not limiting. The various mathematical equations and relationships may govern local discrete aspects in the modeled environment.

Surface modifier 438 may return a function. An agent may of agent model system 420 may call surface modifier 438 to obtain a function that the agent may use modify its properties (e.g., its surface). In some examples, surface modifier 438 may be reflected in a vector. The vector may have any of the properties of the vectors discussed above (e.g., with respect to local discrete model 130 and method step 310). However, alternative data formats may be utilized. The vector or other data format may include one or more callback indicators so that other elements of system 400 may reference (e.g., query) local discrete model 430. The vector or other data format may be packaged in data packet 472 (having any of the properties of data packet 172). As discussed above, data packet 472 may include separate vectors generated by local continuous model 410 and local discrete model 430, or the vectors may be combined. For example, data reflecting local surface 416 and data reflecting surface modifier 438 may be combined into a single data structure (e.g., vector) or may remain in separate data structures (e.g., vectors).

Engine 434 may have any of the properties of engine 414, described above. Engine 434 may function as a classifier. In some examples, engine 434 may be a neural network classifier, which may receive continuous input parameters and return discrete values or functions.

Global continuous model 440 is configured to model one or more continuous global or systemic parameters. For example, global continuous model 440 models global factors that affect an entire environment or ecosystem. Global continuous model 440 may have any of the properties of global continuous model 140.

In an example, global continuous model 440 receives data packet 472 from the local discrete model 430 and in turn generates data packet 474, which can represent or refer to data structures (e.g., via callbacks) that represent such effects. Data packets 472 and 474 may have any of the properties of data packets 172 and 174, respectively.

In an example, global continuous model 440 may utilize input elements 402c, which may include, for example, position and time coordinates. In some examples, input elements 402c may include data received in data packet 472 (which may include data from data packets 470 or 480). An engine 446 may utilize input elements 402c, as well as inputs from energy based models module 442, to generate surface results 448. Energy based models module 442 may store various energy based models that may be utilized to model the environment. As discussed above, global continuous model 440 may utilize principles of Ising fields. In example, energy based models module 442 may include energy based models that utilize Markov Chain Monte Carlo (“MCMC”) techniques to timestep the model, which are then convolved and summed to obtain a scaler. A temperature parameter of the energy based models may be ignored (not utilized or not relevant), fixed, or floating (changing).

In some examples, surface results 448 may be reflected in a vector. The vector may have any of the properties of the vectors discussed above (e.g., with respect to global continuous model 140 and method step 316). However, alternative data formats may be utilized. The vector or other data format may include one or more callback indicators so that other elements of system 400 may reference (e.g., query) global continuous model 440. The vector or other data format may be packaged in data packet 474 (having any of the properties of data packet 174). As discussed above, data packet 474 may include separate vectors generated by local continuous model 410, local discrete model 430, and global continuous model 440, or the vectors may be combined. For example, data reflecting local surface 416, data reflecting surface modifier 438, and data reflecting surface results 448 may be combined into a single data structure (e.g., vector) or may remain in separate data structures (e.g., vectors).

In some examples, engine 446 may be an MCMC engine. In some examples, engine 446 may run numerous times for each time step (delta “t”) (e.g., if a time step is larger than an intrinsic minimum time step of the MCMC, engine 446 may run a number of times in order to obtain the time step/delta “t”). Inputs to engine 446 may depend upon an energy landscape. For example, continuing with the fishing or crab model example, each agent of agent model system 420 may supply a value for its fishing-state, and those values may be summed. A model of agent model system 420 that models ship captains may draw a vector of intents from each captain, build a network of associates of each captain, and apply engine 446 to the network to see if the associates have changed their intents. A graph network vector distance may be calculated and summed to get an energy of the environment/system.

Agent model system 420 is configured to model one or more agents. The modeled agents are allocated compute resources such as memory or processing resources. Each agent can interact with other agent modules/models (of the same type, or different type) of agent model system 420 and also with non-agent modules/models (local continuous model 410, local discrete model 430, and global continuous model 440). The modeled agents are coupled together by environment (modeled by (local continuous model 410, local discrete model 430, and global continuous model 440), which in turn feeds back to agents of agent model system 420.

For example, agent model system 420 receives data packet 474 from global continuous model 440. Based on elements (e.g., vector(s)) of data packet 474, agent model system 420 generates data packet 480, which may include vectors or other data structures representing behaviors of the modeled agents. Data packet 480 may have any of the properties of data packet 180.

In an example, global continuous model 440 may utilize input elements 402d, which may include, for example, position and time coordinates. In some examples, input elements 402d may include data received in data packet 474 (which may include, for example, data from data packets 470 or 472). An engine 446 may utilize input elements 402d, as well as inputs from a behavior equations (e.g., policies and skills) module 422, to generate growth behavior surface 428. Behavior equations module 422 may store various formulas, equations, or other relationships regarding aspects of an agent (e.g., policies, growth, movement, decision-making, etc.). Behavior surface 428 may reflect behaviors of the various agents modeled by agent model system 420. Behavior vector surface 428 may build a vector that is a representation of an action that an agent may take. In some examples, a single growth behavior surface 428 may model all agent types. In other examples, multiple growth behavior surface 428 may be generated (e.g., one for each agent type).

Agent model system 420 may output a data packet 480, which may include vector(s) or other data structures. For example, data packet 480 may reflect (include data relating to) growth behavior surface 428.

Agent model system 420 may have a configurable focus. Different classes of agents may be modeled. A class may represent agents whose behavior is deemed a focus of modeling system 100. For example, a first set of agents of a first class and a second set of agents of a second class may be modeled. In an example, a first set of agents are fish and a second set of agents are ships. Agents may be independent or affected by (dependent on) in part or in whole other by agents of a same class or different class. For example, fish may be dependent upon ships, and vice versa. In some cases, a first class of agents may be part of an intended focus while other agents may be not part of the intended focus but nonetheless modeled anyway because their behavior may affect the agents that are part of the intended focus. For example, system 400 may model ships as agents, although the focus of the model may be fish.

Modeling a given class of agents can vary in sophistication from a large span (capability) to a small span. For example, in some cases, each agent of a class may have agency. Some classes of agents may have greater agency (complex decision making processes) than other agents. For example, in a fishing or crab model, ship captains may have more agency than crabs.

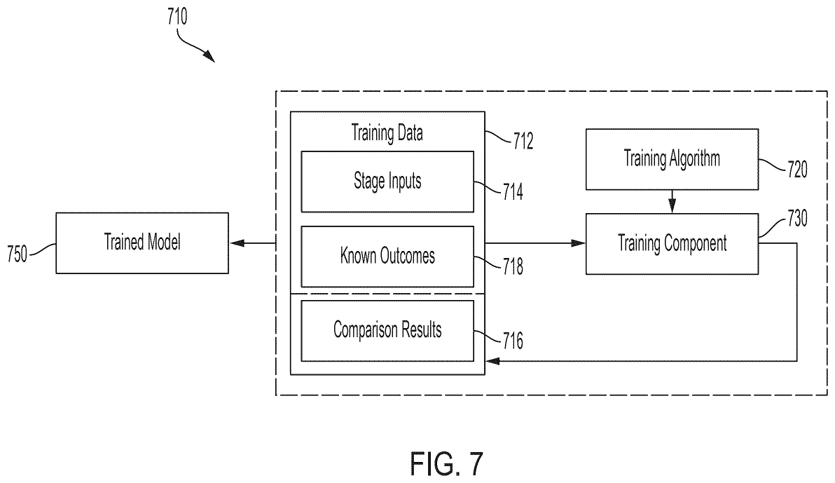

In an example, one machine learning model 427a models a first class of agents. Before deployment, the machine learning model 427a may be trained using the techniques discussed herein, for example, with respect to FIG. 7. For example, training involves determining a set of weights to be applied to one or more models or a class of models such that desirable attributes of agents are programmed. Each agent that is (individual) modeled within a class may have a slight variation in one or more weights, and therefore slightly different behavior. The sets of weights may be on a distribution such as a normal distribution or a bell curve distribution. The sets of weights may reflect environmental or other factors. For instance, a first crab (first agent) may have a first set of weights that reflect that the first crab may react differently to an environment (e.g., a water temperature of an environment) than a second crab (second agent).

Each agent may include a representation of space (x, y) and time (t). The modeled agents can receive inputs of a time (e.g., an absolute time) or a change in time (a relative time versus a previous time). These updates in time can on a periodic basis, e.g., every 1 second, 5 seconds, 1 minute, 1 hour, 1 day, etc. When the input is received, by an agent, the agent may update its location in space. This update may be transmitted to other models of system 100 via data packet 180. In some examples, information (data) may also be transmitted to other modeled agents within agent model system 120. In aspects, information may be shared among agents of agent model system 120 indirectly, after data packet 180 has been transmitted to, for example, local continuous model 110 and propagated via the downstream flow of data from local continuous model 110.

Optimization or control module 450 may function in a similar manner to optimization or control module 150. Optimization or control module 450 can also generate analysis and reports such as analysis 460, which may have any of the properties of analysis 160.

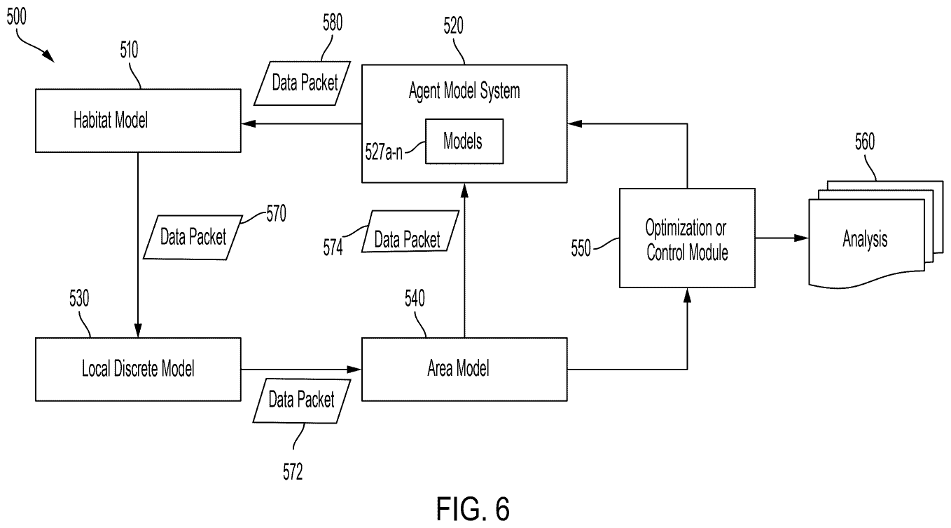

FIG. 6 depicts a system 500 for environmental modeling, in accordance with an aspect of the present disclosure. System 500 provides an illustrative example of the concepts described above. In particular, system 500 may be a system for modeling an ocean ecosystem and, specifically, crabs in an ocean ecosystem. System 500 may make a digital twin of the ocean. Although crabs are described as an example, it will be appreciated that system 500 may model other species by adjusting the modeled parameters to include those that are relevant to the species. System 500 is provided for example purposes only, and the systems above are not limited to modeling such an ecosystem. Aspects of a fishing or crab model that are discussed above may not be repeated here for efficiency but also apply to system 500. System 500 includes a habitat model 510 (which may have any of the properties of local continuous models 110, 410), an agent model system 520 (having any of the properties of agent model systems 120, 420), a local discrete model 530 (having any of the properties of local discrete models 130, 430) and an area model 540 (having any of the properties of global continuous models 140, 440).

System 500 may facilitate answering complex questions about the environment. Example questions may include “what is a crab at the bottom of the ocean going to do?”; “what are schooling fish going to do?”; “what are cod going to do?”; “what are fishermen going to do?”; “what are the counterfactuals that will change what an agent or the environment will do?”; “When should fisheries be opened? “Where should fisheries be opened?;” What should the total allowable catch be?;” and “Where should we encourage or allow people to fish?” System 500 may assist fishing ship fleet managers with deploying their fleet to maximize an amount of fish caught. System 500 may assist a fishery manager with the fishery while allowing maximum extraction from the fishery.

In the example, agents modeled by agent model system 520 may be agents that are relevant to the behavior of crabs. In aspects, crabs may be an agent of focus of system 500. Exemplary agents modeled may include crabs themselves, other animals, such as cod (who have relationships with crab populations, including predator-prey relationships), and fishing boats (or fishing captains). System 500 may additionally or alternatively model other types of fish, other people, government actors, or other larger entities (e.g., corporate entities).

Habitat model 510 may model, using any of the techniques described above, continuous aspects of a local habitat of modeled agents. Habitat model 510 may model, for example, bathymetry, if ice is present on sea surface, features of the local water (e.g., water column temperature, salinity, currents), density of phytoplankton, density of ecosystem trophic levels etc. Habitat model 510 may utilize convection-diffusion or interpolation functions. Habitat model 510 may model parameters (including, e.g., the example parameters listed above) for each relevant point in a habitat. Habitat model 510 may generate a data packet 570 (which may include one or more vectors, as described above). For example, the vector may be surface that includes all of modeled information about a given point in a field modeled by habitat model 510. Habitat model 510 may provide data packet 570 to local discrete model 530.

Local discrete model 530 may use any of the techniques described above to model aspects of a local environment. For example, local discrete model 530 may model predator-prey relationships (e.g., between cod and crabs), crab molting, ship fuel levels (which may determine whether a ship returns to a point), and states of fish (which may indicate what a ship should do next, such as drive to port). Local discrete model 530 may apply, for example, a neural network classifier. Local discrete model 530 generates a vector including the modeled parameters. Local discrete model 530 may include the vector in a data packet 572, which it may provide to the area model 540.

Area model 540 may model, for example, a price of fish, fishing laws (e.g., total allowable catch), economic factors, etc. In an example, each captain of each fishing ship within an area may be represented a vector that describes the captain (e.g., a level of panic of the captain about fuel levels on their ship, how worried the captain is about catching enough fish, etc.). As discussed above, area model 540 may apply field modeling principles, such as energy-based models. Area model 540 may utilize information provided by agent model system 520. A temperature of area model 540 may be zero or null. For example, at the beginning of a fishing season, all of the captains'vectors may be in alignment, and misalignment may develop over time. Area model 540 may generate a vector comprising the modeled data. Area model 540 may, for example, sum agents'actions for a “loss” value. Area model 540 provides a data packet 574 including the vector to agent model system 520 or to optimization or control module 550. An output of area model 540 may be interpreted as an efficiency of the environment/system.

Agent model system 520, as discussed above, may include a plurality of models to model a plurality of different agent types. Agent model system 520 may use data packet 574 to model one or more agent behaviors. For example, agent model system 520 may make callbacks to habitat model 510 or to local discrete model 530. Agent model system 520 may generate one or more vectors, which agent model system 520 may provide to habitat model 510 in a data packet 580. Habitat model 510 may use the data in data packet 580 to model the local area, as described above, and the process may continue to iterate.

Optimization or control module 550 may provide inputs to agent model system 520 or other elements of system 500 in order to optimize system 500 (e.g., in order to optimize an energy function of system 500). For example, using the example of the shipping captains above, the system may seek to cause greater alignment among the vectors of the shipping captains. Adjustments made by optimization or control module 550 may be adjustments that are capable of practically being made. For example, in the crab environment model described with respect to system 500, it may not be possible to optimize a behavior of an individual crab, due to its inherent properties and level of agencies. However, optimization or control module 550 may seek to optimize behavior of ships—for example, optimization or control module may model a system with half as many ships fishing. Optimization or control module 550 may, for example, model adjustments to a fishing laws, such as when fisheries are opened, where fisheries are opened, a total allowable catch, etc.

Other examples are described herein for the purpose of illustrating the scope of the disclosed embodiments. These examples are not limiting and instead are intended to provide further information on flexibility of the disclosed embodiments.

In one example, the systems and methods disclosed herein may be used to model an environment/system that is an economic market. The systems and methods may mix macro- (global) and micro- (local) economic effects and may include agents that may have varying rationality. Thus, the systems and methods disclosed herein may provide a more complete and true picture of an economic market than other systems and models. In some examples, resources and agents that are modeled may have spatial components. Such economic modeling systems and methods may be used to, by way of example, predict market demand and prices, model an economic system, or find market opportunities.

In a system 100, 400 that models economics, local continuous model 110, 410 may model supply. Local continuous model 110, 410 may apply an engine that models supply density at a given point and time. Local discrete model 130, 430 may model demands or productivity. Local discrete model 130, 430 may, for each type/class of supply, provide a baseline of what type/class of agent wants the supply, how much the agent wants, and how much the supply's nominal value is. Local discrete model 130, 430 may also, for each productivity, provide a baseline for what supply and density is needed to produce a given amount, or supply-demand curves. Global continuous model 140, 440 may model market pressure. For example, global continuous model 140, 440 may determine an average amount of shortage (consumed supply). Agents of agent model system 120, 420 may include consumers and producers. Models of agent model system 140, 440 may model use market info in a rational way (biased by a temperature of the system/environment) to consume the things the agent demands and may model an agent's production of what they are capable of producing, with rewards from supply-demand curves.

In such an example, global continuous model 140, 440 may utilize information provided by local continuous models 110, 410 and agent model systems 120, 420, such as consumed supply. A temperature of global continuous model 140, 440 may be fixed but may vary from run to run of system 100 (e.g., vary along time steps). Below a critical temperature, system 100 may model isolated markets. At a critical temperature, system 100 may model a global market. Above a critical temperature, system 100 may model exuberant markets.

In another example, the systems and methods disclosed herein may be utilized to model voting, such as an iterative preference indication (a series of voting). Modeled agents may be agents that have a relationship with one another (e.g., a legislature). Such a system may lack spatial components. The system may model feelings and emotions and how agents convert those feelings and emotions into a vote. The system may also model how group psychology may influence individual agents to modify their votes. Such systems and models may be used to predict a voting outcome, to affect a voting outcome, or to understand outcome dynamics.

In a system 100, 400 that models voting, local continuous model 110, 410 may model a sentiment map. In doing so, local continuous model 110, 410 may apply a map that maps values to sentiment. Positive values may be votes in favor, and negative values may be votes against. Local discrete model 130, 430 may model a graph for a voter. For example, local discrete model 130, 430 may utilize MDP for values of voting option information. Global continuous model 140, 440 may model a broader sentiment. For example, global continuous model 140, 440 may utilize an MCMC engine to allow sentiments that are proximate in the map to affect one another. An agent of agent model system 120, 420 may include a voter. Models of agent model system 120, 420 may determine relevant values for a modeled voter and then, using those values, look up in a matrix what the voter's preference is (e.g., using outputs from the other models).

In the voting example, global continuous model 140, 440 may receive inputs from local continuous model 110, 410. A temperature of global continuous model 140, 440 may be the critical temperature. The energy modeled by global continuous model 140, 440 may be modeled using an Ising-style model. An output of global continuous model 140, 440 may be utilized by an agent to decide how to vote.

In a further example, the disclosed systems and methods may be utilized to model a financial technology (fintech) environment/system, such as a stock market. Such a system/environment may be self-driven with chaotic (efficient market) changes.

In a system 100, 400 that models financial technology, local continuous model 110, 410 may model stock prices. For example, local continuous model 110, 410 may model a price of a given stock at a given time. Local discrete model 130, 430 may model a global graph. For example, local discrete model 130, 430 may model how stocks are correlated and may adjust correlation as time moves forward. In some examples, low correlations may be removed. Global continuous model 140, 440 may model trends, such as up or down trends. For example, global continuous model 140, 440 may build a graph of correlations, and adjust correlations with temperature of the system. Temperature may increase as an average correlation decreases. In examples, a completely uncorrelated market may “freeze.” In examples, an almost uncorrelated market may move almost randomly, and demands that were correlated would be reflected. An agent modeled by agent model system 120, 420 may include a stock. For example, the models of agent model system 120, 420 may use the correlations provided by the other models to adjust price. Optimization or control module 150, 450 may modulate external demand to artificially increase or decrease price pressure.

In this example, global continuous model 140, 440 may utilize a temperature of the environment/system (which may be provided by global continuous model 140, 440) and outputs from local discrete model 130, 430. A temperature of global continuous model 140, 440 may float (vary). Global continuous model 140, 440 may utilize a graph computation. An output of global continuous model 140, 440 may indicate price direction.

In another example, the disclosed systems and methods may be used to model a power grid environment/system. A power grid may include electric power producers (coal power plants, hydropower plants, solar power sources, wind power plants, etc.), electric power consumers (e.g., homes and industry), and the physical wires and controllers that connect them. The systems and methods may be utilized to predict a grid load, to optimize power generation, or to explore outcomes of adding or removing loads (e.g., electric cars or solar roofs).

In a system 100, 400 modeling a power grid, local continuous model 110, 410 may model grid power. For example, local continuous model 110 may model temporal power needs, seasonal power needs, or current power price. Local discrete model 130, 430 may model a graph of power lines, which may be a physical map of power lines. For example, local discrete model 130, 430 may model which networks a generator can connect to, networks of consumers, and any networks to which a generating consumer can connect. Global continuous model 140, 440 may model power change. For example, global continuous model 140, 440 may use a graph to build a map of how power demand has changed since a previous time step at which system 100, 400 ran. Agents modeled by agent model system 120, 420 may include energy generators and power energy consumers. For energy generator agents, models of model system 120, 420 may model how, given demands of networks to limit or generate power, to charge for power. For a consumer agent, models of model system 120, 420 may model drawing on or supplying of power as needed, which may be tempered by price.

In the power grid example, global continuous model 140, 440 may use as an input information obtained from agent model system 120, 420 or local discrete model 130, 430. A temperature of global continuous model 140, 440 may be zero (null). Global continuous model 140, 440 may determine actual energy by, for example, summing changes (deltas) of rates of energy usage. An output of global continuous model 140, 440 may represent a total actual energy usage.

FIG. 7 depicts a method of training a machine learning model, in accordance with an aspect. As shown in flow diagram 610 of FIG. 6, training data 612 may include one or more of stage inputs 614 and known outcomes 618 related to a machine learning model to be trained. The stage inputs 614 may be from any applicable source including a component or set shown in the figures provided herein. The known outcomes 618 may be included for machine learning models generated based on supervised or semi-supervised training. An unsupervised machine learning model might not be trained using known outcomes 618. Known outcomes 618 may include known or desired outputs for future inputs similar to or in the same category as stage inputs 614 that do not have corresponding known outputs.

The training data 612 and a training algorithm 620 may be provided to a training component 630 that may apply the training data 612 to the training algorithm 620 to generate a trained machine learning model 650. According to an implementation, the training component 630 may be provided comparison results 616 that compare a previous output of the corresponding machine learning model to apply the previous result to re-train the machine learning model. The comparison results 616 may be used by the training component 630 to update the corresponding machine learning model. The training algorithm 620 may utilize machine learning networks or models including, but not limited to a deep learning network such as Deep Neural Networks (DNN), Convolutional Neural Networks (CNN), Fully Convolutional Networks (FCN) and Recurrent Neural Networks (RCN), probabilistic models such as Bayesian Networks and Graphical Models, or discriminative models such as Decision Forests and maximum margin methods, or the like. The output of the flowchart 600 may be a trained machine learning model 650.

A machine learning model disclosed herein may be trained by adjusting one or more weights, layers, or biases during a training phase. During the training phase, historical or simulated data may be provided as inputs to the model. The model may adjust one or more of its weights, layers, or biases based on such historical or simulated information. The adjusted weights, layers, or biases may be configured in a production version of the machine learning model (e.g., a trained model) based on the training. Once trained, the machine learning model may output machine learning model outputs in accordance with the subject matter disclosed herein. According to an implementation, one or more machine learning models disclosed herein may continuously update based on feedback associated with use or implementation of the machine learning model outputs.

In general, any process or operation discussed in this disclosure that is understood to be computer-implementable, such as the processes illustrated in the flowcharts disclosed herein, may be performed by one or more processors of a computer system, such as any of the systems or devices in the exemplary environments more processors may also be referred to as an operation. The one or more processors may be configured to perform such processes by having access to instructions (e.g., software or computer-readable code) that, when executed by the one or more processors, cause the one or more processors to perform the processes. The instructions may be stored in a memory of the computer system. A processor may be a central processing unit (CPU), a graphics processing unit (GPU), or any suitable types of processing unit.

A computer system, such as a system or device implementing a process or operation in the examples above, may include one or more computing devices, such as one or more of the systems or devices disclosed herein. One or more processors of a computer system may be included in a single computing device or distributed among a plurality of computing devices. A memory of the computer system may include the respective memory of each computing device of the plurality of computing devices.

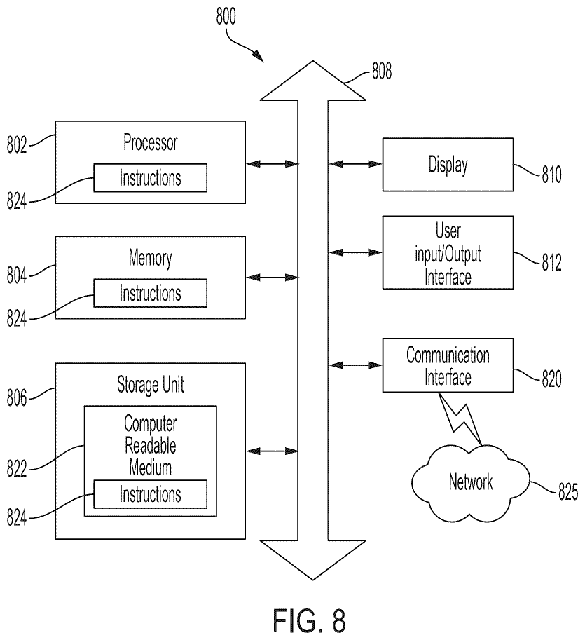

FIG. 8 is a simplified functional block diagram of a computer 700 that may be configured as a device for executing the methods disclosed here, according to exemplary aspects of the present disclosure. For example, the computer 700 may be configured as a system according to exemplary aspects of this disclosure. In various aspects, any of the systems herein may be a computer 700 including, for example, a data communication interface 720 for packet data communication with network 725. The computer 700 also may include a central processing unit (“CPU”) 702, in the form of one or more processors, for executing program instructions. The computer 700 may include an internal communication bus 708, and a storage unit 706 (such as ROM, HDD, SDD, etc.) that may store data on a computer readable medium 722, although the computer 700 may receive programming and data via network communications.

The computer 700 may also have a memory 704 (such as RAM) storing instructions 724 for executing techniques presented herein, for example the methods described with respect to FIGS. 2 and 3, although the instructions 724 may be stored temporarily or permanently within other modules of computer 700 (e.g., processor 702 or computer readable medium 722). The computer 700 also may include input and output ports 712 or a display 710 to connect with input and output devices such as keyboards, mice, touchscreens, monitors, displays, etc. The various system functions may be implemented in a distributed fashion on a number of similar platforms, to distribute the processing load. Alternatively, the systems may be implemented by appropriate programming of one computer hardware platform.

Program aspects of the technology may be thought of as “products” or “articles of manufacture” typically in the form of executable code or associated data that is carried on or embodied in a type of machine-readable medium. “Storage” type media include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer of the mobile communication network into the computer platform of a server or from a server to the mobile device. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links, or the like, also may be considered as media bearing the software. As used herein, unless restricted to non-transitory, tangible “storage” media, terms such as computer or machine “readable medium” refer to any medium that participates in providing instructions to a processor for execution.

While the disclosed methods, devices, and systems are described with exemplary reference to transmitting data, it should be appreciated that the disclosed embodiments may be applicable to any environment, such as a desktop or laptop computer. Also, the disclosed embodiments may be applicable to any type of Internet protocol.

It should be appreciated that in the above description of exemplary embodiments of the invention, various features of the invention are sometimes grouped together in a single embodiment, figure, or description thereof for the purpose of streamlining the disclosure and aiding in the understanding of one or more of the various inventive aspects. The disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the Detailed Description are hereby expressly incorporated into this Detailed Description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those skilled in the art. For example, in the following claims, any of the claimed embodiments can be used in any combination.

Thus, while certain embodiments have been described, those skilled in the art will recognize that other and further modifications may be made thereto without departing from the spirit of the invention, and it is intended to claim all such changes and modifications as falling within the scope of the invention. For example, functionality may be added or deleted from the block diagrams and operations may be interchanged among functional blocks. Steps may be added or deleted to methods described within the scope of the present invention.

The above disclosed subject matter is to be considered illustrative, and not restrictive, and the appended claims are intended to cover all such modifications, enhancements, and other implementations, which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description. While various implementations of the disclosure have been described, it will be apparent to those of ordinary skill in the art that many more implementations are possible within the scope of the disclosure. Accordingly, the disclosure is not to be restricted except in light of the attached claims and their equivalents.

1. A method of modeling one or more agents within an environment, the method comprising:
determining, by a local continuous model, one or more local continuous aspects of a local area proximate to the one or more agents;
constructing, by the local continuous model, a first data packet comprising first data indicative of the one or more local continuous aspects, wherein the first data includes at least one callback indicator to the local continuous model;
providing the first data packet to a local discrete model;
determining, by the local discrete model, one or more local discrete aspects of a local area proximate to the one or more agents;
constructing, by the local discrete model, a second data packet comprising the first data and second data indicative of the one or more local discrete aspects, wherein the second data includes at least one callback indicator to the local discrete model;
providing the second data packet to a global continuous model;
determining, by the global continuous model using the second data packet, including the first data having the at least one callback indicator to the local continuous model and the second data including at least one callback indicator to the local discrete model, one or more global continuous aspects of the environment;
constructing, by the global continuous model, a third data packet including the first data, the second data, and third data indicative of the one or more global continuous aspects;
providing the third data packet to a modeling system comprising one or more agent models, each of the one or more agent models associated with a respective agent of the one or more agents; and
using the third data packet, determining, via the one or more agent models, one or more behaviors of the one or more agents.

2. (canceled)

3. The method of claim 1, wherein using the third data packet includes making callbacks to the local continuous model and the local discrete model based on the at least one callback indicator.

4. The method of claim 1, wherein the one or more local continuous aspects are one or more first local continuous aspects determined at a first time, the method further comprising:
providing the one or more behaviors of the one or more agents to the local continuous model and determining, by the local continuous model, one or more second local continuous aspects of the local area proximate to the one or more agents at a second time.

5. The method of claim 1, wherein the one or more agents include agents of a first class and agents of a second class, and wherein the one or more agent models include a first machine learning model trained to model the first class and a second machine learning model trained to model the second class.

6. The method of claim 5, wherein the one or more agent models include a plurality of instantiations of the first machine learning model, each instantiation of the first machine learning model configured to model an agent of the first class, and a plurality of instantiations of the second machine learning model, each instantiation of the second machine learning model configured to model an agent of the second class.

7. The method of claim 1, wherein the one or more agent models includes a plurality of instantiations of the one or more agent models, and wherein at least some of the plurality of instantiations of the one or more agent models have different parameters or weights from one another.

8. The method of claim 1, further comprising:
receiving, from an optimization or control module, a set of counterfactual parameters that indicate a change to one or more conditions of the environment; and
providing the set of counterfactual parameters to the one or more agent models.

9. The method of claim 1, wherein the global continuous model is an energy-based model.

10. The method of claim 1, wherein the environment is an ocean, and wherein the one or more agents include a ship or an animal.

11. A system for modeling one or more agents within an environment, the system comprising:
at least one data storage device storing instructions for modeling one or more agents within an environment; and
at least one processor configured to execute the instructions to perform operations comprising:
determining, by a local continuous model, one or more local continuous aspects of a local area proximate to the one or more agents;
constructing, by the local continuous model, a first data packet comprising first data indicative of the one or more local continuous aspects, wherein the first data includes at least one callback indicator to the local continuous model;
providing the first data packet to a local discrete model;
determining, by the local discrete model, one or more local discrete aspects of a local area proximate to the one or more agents;
constructing, by the local discrete model, a second data packet comprising the first data and second data indicative of the one or more local discrete aspects, wherein the second data includes at least one callback indicator to the local discrete model;
providing the second data packet to a global continuous model;
determining, by the global continuous model using the second data packet, including the first data having the at least one callback indicator to the local continuous model and the second data including at least one callback indicator to the local discrete model, one or more global continuous aspects of the environment;
constructing, by the global continuous model, a third data packet including the first data, the second data, and third data indicative of the one or more global continuous aspects;
providing the third data packet to a modeling system comprising one or more agent models, each of the one or more agent models associated with a respective agent of the one or more agents; and
using the third data packet, determining, via the one or more agent models, one or more behaviors of the one or more agents.

12. (canceled)

13. The system of claim 11, wherein using the third data packet includes making callbacks to the local continuous model and the local discrete model based on the at least one callback indicator.

14. The system of claim 11, wherein the one or more local continuous aspects are one or more first local continuous aspects determined at a first time, the operations further comprising:
providing the one or more behaviors of the one or more agents to the local continuous model and determining, by the local continuous model, one or more second local continuous aspects of the local area proximate to the one or more agents at a second time.

15. The system of claim 11, wherein the one or more agents include agents of a first class and agents of a second class, and wherein the one or more agent models include a first machine learning model trained to model the first class and a second machine learning model trained to model the second class.

16. A non-transitory computer-readable medium storing instructions that, when executed by one or more processors, cause the one or more processors to perform a method for modeling one or more agents within an environment, the method comprising:
determining, by a local continuous model, one or more local continuous aspects of a local area proximate to the one or more agents;
constructing, by the local continuous model, a first data packet comprising first data indicative of the one or more local continuous aspects, wherein the first data includes at least one callback indicator to the local continuous model;
providing the first data packet to a local discrete model;
determining, by the local discrete model, one or more local discrete aspects of a local area proximate to the one or more agents;
constructing, by the local discrete model, a second data packet comprising the first data and second data indicative of the one or more local discrete aspects, wherein the second data includes at least one callback indicator to the local discrete model;
providing the second data packet to a global continuous model;
determining, by the global continuous model using the second data packet, including the first data having the at least one callback indicator to the local continuous model and the second data including at least one callback indicator to the local discrete model, one or more global continuous aspects of the environment;
constructing, by the global continuous model, a third data packet including the first data, the second data, and third data indicative of the one or more global continuous aspects;
providing the third data packet to a modeling system comprising one or more agent models, each of the one or more agent models associated with a respective agent of the one or more agents; and
using the third data packet, determining, via the one or more agent models, one or more behaviors of the one or more agents.

17. (canceled)

18. The non-transitory computer-readable medium of claim 16, wherein using the third data packet includes making callbacks to the local continuous model and the local discrete model based on the at least one callback indicator.

19. The non-transitory computer-readable medium of claim 16, wherein the one or more local continuous aspects are one or more first local continuous aspects determined at a first time, the method further comprising:
providing the one or more behaviors of the one or more agents to the local continuous model and determining, by the local continuous model, one or more second local continuous aspects of the local area proximate to the one or more agents at a second time.

20. The non-transitory computer-readable medium of claim 16, wherein the one or more agents include agents of a first class and agents of a second class, and wherein the one or more agent models include a first machine learning model trained to model the first class and a second machine learning model trained to model the second class.

21. The method of claim 1, further including using the one or more behaviors of the one or more agents to determine which fisheries to open, when fisheries are opened, where fisheries are opened, or a total allowable catch.

22. The method of claim 1, further including using the one or more behaviors of the one or more agents to deploy a fleet of ships to maximize an amount of fish caught.

23. The method of claim 1, further including using the one or more behaviors of the one or more agents to adjust a law managing a fishery.
